(19) United States
(12) Patent Application Publication
(10) Pub. No.: US 2024/0386169 A1
(43) Pub. Date: Nov. 21, 2024

(54) Data Driven Discovery of Unconventional Reservoir Physics

(71) Applicant: XECTA INTELLIGENT PRODUCTION SERVICES, Houston, TX (US)

(72) Inventors: Sathish Sankaran, Spring, TX (US); Hardikkumar Zalavadia, Richmond, TX (US); Utkarsh Sinha, Houston, TX (US); Prithvi Singh Chauhan, Bryan, TX (US)

(21) Appl. No.: 18/663,520

(22) Filed: May 14, 2024

Related U.S. Application Data
(60) Provisional application No. 63/502,975, filed on May 18, 2023.

(51) Int. Cl. G06F 30/28

(52) U.S. Cl. CPC G06F 30/28

(57) ABSTRACT

A method of forecasting production of a well penetrating a reservoir in a subterranean formation, including: receiving a plurality of bottomhole pressures for the well; receiving a plurality of flowrates for the well; determining rate normalized pressure (RNP) data for the well over a period of time based on the plurality of bottomhole pressure and the plurality of flowrates; performing a sparse identification of nonlinear dynamics (SINDy) analysis on the RNP data to identify a relationship between flowrate and bottomhole pressure for the well, wherein the SINDy analysis is based on a plurality of physics features; providing a forecast of future production for the well based on the identified relationship between flowrate and bottomhole pressure for the well; and producing fluids from the reservoir based, at least in part, on the forecast of future production.

### CROSS-REFERENCE TO RELATED APPLICATION

This application claims priority to U.S. Provisional Application No. 63/502,975 filed May 18, 2023 entitled “DATA DRIVEN DISCOVERY OF UNCONVENTIONAL RESERVOIR PHYSICS” by Sathish Sankaran, Hardikkumar Zalavadia, Utkarsh Sinha, and Prithvi Singh Chauhan, which is incorporated herein by reference as if reproduced in its entirety.

### TECHNICAL FIELD

This invention relates to forecasting well production in unconventional reservoirs and, more particularly, to methods for forecasting well production based on a relationship between flow rate and bottomhole pressure identified using a hybrid data-driven and physics-informed model.

### BACKGROUND

Understanding well production performance in hydrocarbon reservoirs in a timely manner is essential for optimizing reservoir management, improving operational efficiency, and maximizing asset value for producers and operators. As operations extend to more complex reservoirs, the industry is faced with challenges to effectively assess and develop these fields. Early understanding of reservoir performance and mitigating remaining uncertainties are important to earning the maximum possible benefit from the assets. For example, unconventional reservoirs, such as shale gas and tight oil formations, are becoming increasingly important for the global energy industry. Despite the significant growth of production from these reservoirs in recent years, forecasting their production has proven to be a challenging task. However, there is a lack of robust methods for tracking and detecting well performance degradation for optimal reservoir management. In common practice, well productivity is often evaluated through manual interpretations of planned well events (e.g., shut-ins, well tests, etc.). Traditional techniques for production forecasting, such as decline curve analysis (DCA), rate transient analysis (RTA), and numerical simulation, struggle to capture the complex physics and operational pace of unconventional reservoirs, resulting in unreliable production forecasts.

In some embodiments, although improvements have been made to traditional DCA techniques, they do not significantly address the varying bottomhole pressure situation and nonlinear processes which are often seen in the unconventional reservoirs. While numerical models may incorporate very complex physics combining geological, geomechanical, and production data, they are often not conducive for continuous model updates and production optimization purposes for thousands of wells every day.

In some embodiments, traditional RTA methods may fundamentally address this issue through explicit analytical, semi-analytical, or numerical formulations using superposition principles. However, non-linearities such as compressible gas flow, pressure-dependent permeability, and other fluid properties require pseudo-pressure and pseudo-time transformations to keep the traditional RTA methods tractable. As a result, the traditional RTA methods often follow a manual process that involves three stages: diagnostics, model calibration, and forecasting. The diagnostic stage is concerned with identifying one or more dominant flow regimes at any time interval and applying a mechanistic model to infer some key parameters which describe fluid flow based on the assumed mechanistic model. The key assumptions for analytical formulation may often include the following: homogeneous reservoir, planar and perpendicular fractures, fracture geometry symmetry, equally spaced fractures, a pre-determined number of actual fractures, constant fracture properties across all stages, known fluid properties and petrophysical inputs, pre-established flow pathways (e.g. linear, radial, etc.), no production interference with offset wells, etc. In some embodiments, the traditional RTA methods may relax some of these assumptions and involve a numerical RTA path which is doomed by the same limitations of numerical simulations with computational complexity. For example, a fractional RTA method may relax the assumption of equally spaced fractures to include heterogeneous fracture spacing (fracture swarms, random fractures) and capture the compound effect on the overall well performance. However, the fractional RTA method is still susceptible to the other limitations of the traditional RTA methods.

It is now recognized that a need exists for a robust and scalable method for forecasting the production of wells in unconventional reservoirs, which can be applied in a practical and automated manner.

### BRIEF DESCRIPTION OF THE DRAWINGS

These drawings illustrate certain aspects of some of the embodiments of the present disclosure and should not be used to limit or define the claims.

FIG. 1 illustrates a schematic illustrating classifications of fractures from simple to complex fractures for an unconventional reservoir, in accordance with certain embodiments.

FIG. 2 illustrates a schematic of an example framework of using a sparse identification of nonlinear dynamics (SINDy) regression to identify dominant and relevant terms in a dynamical model, in accordance with certain embodiments.

FIG. 3 illustrates a schematic of a conceptual model of a vertical well with an infinite conductivity fracture extending to the boundary of a closed reservoir, in accordance with certain embodiments.

FIG. 4 illustrates a schematic of an example progression of potential flow regimes in a multi-fractured horizontal well (MFHW), in accordance with certain embodiments.

FIG. 5 illustrates a schematic of a conceptual model of a simultaneous inter-fracture flow and boundary dominated flow, in accordance with certain embodiments.

FIG. 6 illustrates a schematic of a conceptual model of a complex fracture network, in accordance with certain embodiments.

FIGS. 7A and 7B illustrate plots illustrating examples of sub-linear and sub-radial flow regimes, respectively, in accordance with certain embodiments.

FIG. 8 illustrates a flow chart of an example method of forecasting the production of a well penetrating a reservoir in a subterranean formation, in accordance with certain embodiments.

FIG. 9 illustrates a flow chart of another example method of forecasting the production of a well penetrating a reservoir in a subterranean formation, in accordance with certain embodiments.

FIG. 10 illustrates a flow chart of another example method of forecasting the production of a well penetrating a reservoir in a subterranean formation, in accordance with certain embodiments.

FIG. 11 illustrates a block diagram showing an example information handling system in accordance with certain embodiments of the present disclosure, in accordance with certain embodiments.

FIGS. 12A and 12B illustrate plots of predicted vs. actual rate normalized pressure (RNP) data for a machine learning training portion and a test portion, respectively, taken from a 1,000 day dataset, in accordance with certain embodiments.

FIGS. 13A and 13B illustrate plots of predicted vs. actual RNP data for a machine learning training portion and a test portion, respectively, taken from a 5,000 day dataset, in accordance with certain embodiments.

FIGS. 14A-14D illustrate plots showing the importance of various coefficients with time for actual data for a 1,000 day dataset (FIG. 14A), predicted data for a 1,000 day dataset (FIG. 14B), actual data for a 5,000 day dataset (FIG. 14C), and predicted data for a 5,000 day dataset (FIG. 14D), in accordance with certain embodiments.

FIGS. 15A-15C illustrate plots of predicted vs. actual RNP data for a machine learning training portion (FIG. 15A) and a test portion (FIG. 15B), and a plot showing selected coefficient contribution with time (FIG. 15C), in accordance with certain embodiments.

FIGS. 16A-16C illustrate plots of a predicted and an actual oil rate profile (FIG. 16A), and predicted vs. actual flowrate data for a machine learning training portion (FIG. 16B) and a test portion (FIG. 16C), in accordance with certain embodiments.

FIGS. 17A-17D illustrate plots of actual RNP vs. time on a log-log plot (FIG. 17A), predicted RNP vs. time on a log-log plot (FIG. 17B), and predicted vs. actual RNP data for a machine learning training portion (FIG. 17C) and a test portion (FIG. 17D), in accordance with certain embodiments.

FIG. 18 illustrates a plot showing coefficient contribution with time for an infinite reservoir boundary condition, in accordance with certain embodiments.

FIGS. 19A and 19B illustrate plots of BHP profile used as an input to a model (FIG. 19A) and a corresponding RNP profile generated for the model (FIG. 19B), in accordance with certain embodiments.

FIGS. 20A-20C illustrate plots of a predicted and an actual oil rate profile (FIG. 20A), and predicted vs. actual flowrate data for a machine learning training portion (FIG. 20B) and a test portion (FIG. 20C), in accordance with certain embodiments.

FIGS. 21A-21C illustrate plots of a predicted and an actual oil rate profile (FIG. 21A), and predicted vs. actual flowrate data for a machine learning training portion (FIG. 21B) and a test portion (FIG. 21C), in accordance with certain embodiments.

FIGS. 22A and 22B illustrate plots showing coefficient contribution with time for a 75% training data machine learning model and a 90% training data machine learning model, in accordance with certain embodiments.

FIG. 23A illustrates a schematic view of a MFHW with irregular spaced fractures, and FIG. 23B illustrates a log-log plot of a corresponding RNP profile with respect to time, in accordance with certain embodiments.

FIGS. 24A-24C illustrate plots of a predicted and an actual oil rate profile (FIG. 24A), and predicted vs. actual flowrate data for a machine learning training portion (FIG. 24B) and a test portion (FIG. 24C), in accordance with certain embodiments.

FIGS. 25A-25C illustrate plots of a predicted and an actual RNP profile (FIG. 25A), and predicted vs. actual RNP data for a machine learning training portion (FIG. 25B) and a test portion (FIG. 25C), in accordance with certain embodiments.

FIG. 26 illustrates a plot showing coefficient contribution with time for a closed boundary condition with unevenly spaced fractures, in accordance with certain embodiments.

FIG. 27A illustrates a schematic view of a MFHW with unequal fracture half lengths, and FIG. 27B illustrates a log-log plot of a corresponding RNP profile with respect to time, in accordance with certain embodiments.

FIGS. 28A-28C illustrate plots of a predicted and an actual RNP profile (FIG. 28A), a predicted and actual oil rate profile (FIG. 28B) with respect to time, and predicted vs. actual flowrate data for a test portion (FIG. 28C), in accordance with certain embodiments.

FIG. 29 illustrates a plot showing coefficient contribution with time for a closed boundary condition with unequal fracture lengths and finite conductivity, in accordance with certain embodiments.

FIGS. 30A and 30B illustrate plots of measured gas rates and BHP, respectively, with respect to time for a gas well, in accordance with certain embodiments.

FIG. 31 illustrates a plot of gas RNP vs material balance time (MBT) for the gas well, in accordance with certain embodiments.

FIG. 32A illustrates a plot of predicted and actual gas RNP with respect to MBT for the gas well, in accordance with certain embodiments.

FIG. 32B illustrates a plot showing coefficient contribution with MBT for the gas well, in accordance with certain embodiments.

FIGS. 33A-33C illustrate plots of a predicted and an actual gas rate vs. MBT (FIG. 33A), and predicted vs. actual gas rate data for a machine learning training portion (FIG. 33B) and a test portion (FIG. 33C), in accordance with certain embodiments.

FIGS. 34A and 34B illustrate plots of measured oil rates and BHP, respectively, with respect to time for an oil well, in accordance with certain embodiments.

FIG. 35 illustrates a plot of oil RNP vs material balance time (MBT) for the oil well, in accordance with certain embodiments.

FIG. 36A illustrates a plot of predicted and actual oil RNP with respect to MBT for the oil well, in accordance with certain embodiments.

FIG. 36B illustrates a plot showing the coefficient contribution with MBT for oil production from the oil well, in accordance with certain embodiments.

FIGS. 37A-37C illustrate plots of a predicted and an actual oil rate vs. MBT (FIG. 37A), and predicted vs. actual oil rate data for a machine learning training portion (FIG. 37B) and a test portion (FIG. 37C), in accordance with certain embodiments.

FIG. 38A illustrates a plot of predicted and actual liquid RNP with respect to MBT for the oil well, in accordance with certain embodiments.

FIG. 38B illustrates a plot showing the coefficient contribution with MBT for liquid production from the oil well, in accordance with certain embodiments.

FIGS. 39A-39C illustrate plots of a predicted and an actual liquid rate vs. MBT (FIG. 39A), and predicted vs. actual liquid rate data for a machine learning training portion (FIG. 39B) and a test portion (FIG. 39C), in accordance with certain embodiments.

FIG. 40 illustrates a flow chart of another example method of forecasting the production of a well penetrating a reservoir in a subterranean formation, in accordance with certain embodiments.

While embodiments of this disclosure have been depicted and described and are defined by reference to exemplary embodiments of the disclosure, such references do not imply a limitation on the disclosure, and no such limitation is to be inferred. The subject matter disclosed is capable of considerable modification, alteration, and equivalents in form and function, as will occur to those skilled in the pertinent art and having the benefit of this disclosure. The depicted and described embodiments of this disclosure are examples only, and not exhaustive of the scope of the disclosure.

### DETAILED DESCRIPTION

Illustrative embodiments of the present disclosure are described in detail herein. In the interest of clarity, not all features of an actual implementation may be described in this specification. It will of course be appreciated that in the development of any such actual embodiment, numerous implementation-specific decisions may be made to achieve the specific implementation goals, which may vary from one implementation to another. Moreover, it will be appreciated that such a development effort might be complex and time-consuming, but would nevertheless be a routine undertaking for those of ordinary skill in the art having the benefit of the present disclosure.

The present disclosure relates to methods for forecasting well production based on a relationship between flowrate and bottomhole pressure identified using a hybrid data-driven and physics informed model.

More specifically, the present disclosure provides a method of forecasting production of a well penetrating a reservoir in a subterranean formation, comprising: receiving a plurality of bottomhole pressures for the well; receiving a plurality of flowrates for the well; determining rate normalized pressure (RNP) data for the well over a period of time based on the plurality of bottomhole pressure and the plurality of flowrates; performing a sparse identification of nonlinear dynamics (SINDy) analysis on the RNP data to identify a relationship between flowrate and bottomhole pressure for the well, wherein the SINDy analysis is based on a plurality of physics features in a regression library; providing a forecast of future production for the well based on the identified relationship between flowrate and bottomhole pressure for the well; and producing fluids from the reservoir based, at least in part, on the forecast of future production.

In some embodiments, the present disclosure provides a method of forecasting production of a well penetrating a reservoir in a subterranean formation, comprising: receiving a plurality of bottomhole pressures for the well; receiving a plurality of flowrates for the well; training a machine learning model based on the plurality of bottomhole pressures and the plurality of flowrates for the well; performing a sparse nonlinear regression (SNR) analysis on the machine learning model to predict future production of the well, wherein the SNR analysis is based on a plurality of physics features in a regression library; and producing fluids from the reservoir based, at least in part, on the predicted future production of the well.

In some embodiments, the present disclosure provides a method of forecasting production of a well penetrating a reservoir in a subterranean formation, comprising: receiving a plurality of bottomhole pressures for the well; receiving a plurality of flowrates for the well; determining rate normalized pressure (RNP) data for the well based on the plurality of bottomhole pressure and the plurality of flowrates; training a machine learning model based on the RNP data for the well; performing a sparse nonlinear regression (SNR) analysis on the machine learning model to predict future RNP values for the well, wherein the SNR analysis is based on a plurality of physics features in a regression library; and producing fluids from the reservoir based, at least in part, on the future RNP values for the well.

In some embodiments, the disclosed disclosure provides a hybrid data-driven and physics informed model based on one or more sparse nonlinear regression (SNR) methods for identifying rate-pressure relationships in unconventional wells. Utilizing recent developments in machine learning and sparsity techniques, the disclosed hybrid SNR methods may include a novel framework for determining governing equations underlying fluid flow in unconventional reservoirs. The disclosed hybrid SNR methods may determine a model associated with the unconventional wells by utilizing a regression library of data-driven functions along with information from standard flow-regime equations which form the basis for traditional RTA. Thus, the model may be a hybrid data-driven and physics informed model. For example, the model may include one or more fixed known relationships of pressure and rates which are applicable only under certain assumptions (e.g. planar fractures, single-phase flowing conditions, etc.). As another example, the model may include one or more nonlinear relationships of pressure and rates which are applicable to complex, non-uniform fractures, and multi-phase flow of fluids which do not follow the same diagnostics behavior as planar fractures and single-phase flow, but exhibit more complex behavior not explained by analytical equations. To forecast the well for various flowing pressures and operating conditions, the disclosed hybrid SNR methods may be implemented to determine the model associated with the unconventional wells by identifying these complexities by combining the most important pressure and time features that explain the behavior of the phase rates. In addition, the disclosed SNR methods may allow the identification of dominant flow regimes through the highest contributing terms without performing typical line-fitting procedures.

In some embodiments, the disclosed hybrid SNR methods have been validated using a benchmark model with varying and constant bottomhole pressures (BHP). The disclosed hybrid SNR methods are then applied for complex real field cases on multi-phase wells. The findings show that the model is accurate enough to identify the features which control rate-pressure behavior and to predict production for new BHPs.

Among the many potential advantages to the methods and systems of the present disclosure, only some of which are alluded to herein, the methods of the present disclosure are robust since they can be applied to any well, regardless of fluid type or flow conditions, and can be applied to any reservoir complexity because it does not depend on mechanistic fractures or simulation model assumptions. The disclosed methods use hybrid SNR to resolve several modes that govern a well's flow process simultaneously, thus providing physical insights on the prevailing multiple complex flow regimes. In particular, the disclosed hybrid SNR methods may enable the identification of one or more dominant flow regimes by using terms with the highest contributions instead of the usual line fitting procedure.

In some embodiments, for existing wells in unconventional fields to remain profitable, regularly analyzing and forecasting well performance under various operational strategies is critical to maintaining their profitability. There is also a growing need to create models that are scalable across the entire field. Pure data-driven methodologies, like decline curve analysis (DCA) and machine learning based methods, fall short in capturing essential physical components, compounded by a lack of one or more key operational parameters, such as pressures and fluid property changes across a large number of wells. This is made worse by the absence of key operational parameters, including PVT and fluid property changes across several wells. Traditional models such as numerical simulations face a scalability challenge to extend to large well counts with a rapid pace of operations. Another widely used method is rate transient analysis (RTA). However, traditional methods like RTA tend to be interpretive and not suitable for field-scale applications because prior knowledge, such as flow regimes and mechanistic model assumptions, plays an important role in the traditional methods in reservoir modeling. Thus, the proposed hybrid SNR methods may significantly improve the traditional methods by implementing an automated workflow to determine one or more data-driven and physics-constrained reservoir models from routine data (rates and pressures) for pressure-aware production forecasting.

In some embodiments, the proposed hybrid SNR methods may make use of a regression library of data-driven functions as well as features from common flow-regime equations. The hybrid SNR methods may be implemented to use production and pressure data to determine one or more governing equations underlying fluid flow in an unconventional reservoir by leveraging advances in sparsity techniques and machine learning. For example, the hybrid SNR method may be implemented to determine a hybrid data-driven and physics informed model based on sparse nonlinear regression for identifying rate-pressure relationships in the unconventional reservoir. In some embodiments, the hybrid SNR methods may constrain the hybrid data-driven and physics-informed model using one or more known fixed relationships between pressure and rates, which are applicable under specific hypotheses (planar fractures, single-phase flowing conditions, etc.). Furthermore, the hybrid SN may constrain the hybrid data-driven and physics informed model by allowing for the proposal of multiple functional forms for pressure and time. Thus, the hybrid SNR methods may resolve one or more proper functions by identifying the dominating multiple complex flow regimes from the regression library. As a result, the hybrid SNR methods may be applicable to complex, non-uniform fractures and multi-phase flow of fluids, which do not follow the same diagnostics behavior but exhibit more complex behavior not explained by analytical equations.

In some embodiments, the hybrid SNR methods may be implemented to identify complex and nonlinear dynamic behavior associated with an unconventional reservoir for a given well from a combination of the most relevant pressure and time features that explain the phase rate behavior for the well. For example, the hybrid SNR methods may be implemented to identify one or more features which govern the flow process simultaneously in the unconventional reservoir which dictate rate-pressure behavior and perform production forecasts for new bottom-hole pressure profiles. Thus, the hybrid SNR methods may be implemented to accurately forecast the well for different flowing pressure/operating conditions by identifying one or more dominant flow regimes through the highest contributing terms without performing a typical line fitting procedure. Therefore, the hybrid SNR methods may be efficiently applied to any reservoir complexity in the unconventional reservoir with different fluid types and flowing conditions without providing any mechanistic fracture or simulation model assumptions.

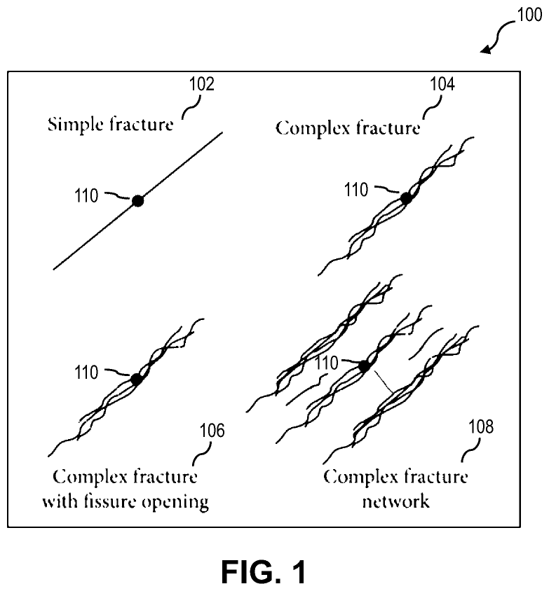

FIG. 1 illustrates a schematic illustrating classifications of fractures from simple to complex fractures for an unconventional reservoir 100, in accordance with certain embodiments. For example, the development of production of shale gas/shale oil may be made possible through horizontal wells 110 with multiple transverse fractures. In order to optimize the well hydraulic fracturing design for exploration and production, a fracture model may include a plurality of key parameters which characterize a fracture network associated with the unconventional reservoir. In some embodiments, the fracture model may be characterized by various hydraulic fracture test site (HFTS) results which show three types of fracture extensions when intersecting with natural fractures: 1) crossing the natural fractures, 2) extending along the natural fractures, and 3) crossing and extending along at the same time. Based on the fracture extension types formed during a fracturing process of naturally fractured formations, hydraulic fractures may be classified into four major types: 1) a simple fracture 102 including a single bi-wing planar fracture geometry, 2) a complex fracture 104 including multiple fractures, 3) a complex fracture with fissure opening 106 including open natural fractures, and 4) a complex fracture network 108. For example, the complex fracture network 108 may highly form under a low fluid viscosity injection during the fracturing process of naturally fractured formations. As another example, a multi-fracture network may form in shale reservoir area in which multiple dominant fracture systems with different dynamics coexist and act concurrently on the well performance. Thus, the multi-fracture network may form a nonlinear dynamic system which increases stimulated reservoir volume (SRV) to improve well performance where treatment success relies on whether hydraulic fracture may extend to form multi-fracture network. Furthermore, the emergent behavior of the fractures in the multi-fracture network may change from the stage level to the segment level to the well level.

In some embodiments, one or more governing equations may be implemented to accurately simulate a fractured flow behavior associated with the performance of unconventional reservoir 100. The one or more governing equations may be used to determine a mathematical model which may be implemented to predict one or more output reservoir parameters, such as rate normalized pressure (RNP), oil rate, gas rate, etc., using a plurality of input parameters, such as initial reservoir pressure, flow rate, formation volume factor, viscosity, distance from fracture to outer boundary, porosity, total compressibility, formation permeability, net formation thickness, number of fractures, etc. The fractured flow behavior in the unconventional reservoir is routinely modeled using a single lumped flow regime at any instant in a traditional RTA method. Thus, the traditional RTA method may require the identification of the single lumped flow regime and mechanistic model assumptions. However, multiple dominant fracture systems with different dynamics may coexist and act concurrently on the well performance. As a result, accurate models are critical to gaining a fundamental understanding of physical processes and extracting process dynamics from observed field data. The accurate models may not rely on any modeling assumptions in order to extract the process dynamics from observed field data.

In some embodiments, for unconventional operations, time series data is available in the form of flow rates (“rates”) and pressures, typically at a daily frequency. Thus, the disclosed hybrid SNR methods may be used to efficiently determine a scalable reservoir model, such as a hybrid data-driven and physics informed model, to characterize the coexistence of multiple dynamics based on the observed field data. In some embodiments, a modeling method based on data-driven model discovery may be an approach to a data-driven discovery of physics (D3P) model discovery which attempts to balance model efficiency with the model's interpretive capabilities. The D3P model discovery may be implemented to develop an automated model discovery system that relies on the construction of one or more D3P models representing the multi-fracture network of the unconventional reservoir. For example, a principled D3P approach may attempt to elicit equations of motion (EoM) from time-series data. One or more symbolic regression and evolutionary algorithms may be used to directly determine a nonlinear dynamic system of the fractured flow behavior in the unconventional reservoir from routinely collected field data. For example, a regression-based sparse identification of nonlinear dynamics (SINDy) formulation may combine sparsity-promoting techniques and machine learning with nonlinear dynamical systems to discover one or more governing physical equations based purely on measured field data. The key assumption in the SINDy formulation may be that a nonlinear function ƒ(x(t)) which describes the equation of motion of a dynamical system consists of a few terms, making the governing equations sparse in a high-dimensional nonlinear system. This assumption may hold true for many physical systems. Thus, sparse regression methods may make this concept of sparsity favorable, since these algorithms can efficiently determine a plurality of terms of the nonlinear function ƒ(x(t)) using a regression library. As a result, SINDy may avoid overfitting by selecting parsimonious models that balance model accuracy with complexity via Pareto analysis.

In some embodiments, other sparse regression schemes have been introduced for D3P model recovery for handling noisy data and regressions without pre-selected basis functions. For example, a probabilistic framework may also be used, where Gaussian processes are used for probabilistic inference over functions. While the D3P-based methods use the field measurements as-is, without knowledge of the proper coordinates, standard approaches sometimes fail to discover the underlying dynamical model associated with the fractured flow behavior in the unconventional reservoir. Thus, these D3P-based methods may advance the ability to use computations and data for the discovery of governing physical laws. In some embodiments, a deep extended dynamic mode decomposition (Deep EDMD) method may be implemented to reconstruct unconventional reservoir flow/fracture dynamics, which are either partially or entirely unknown or too complex to formulate using existing simulation models. However, available reservoir saturation and pressure distributions are difficult to obtain for such training models.

In some embodiments, the D3P models may be applied for reservoir surveillance of conventional reservoirs to capture pressure transient behavior and the relationship between pressure and rate. The proposed hybrid SNR methods may be used to generate a library of selectable data modeling primitives based on a plurality of data-driven and physics-motivated basis functions which serve as the basic building blocks for complex modeling pipelines. Thus, the proposed hybrid SNR methods may be used to identify rate-pressure relationships in unconventional reservoirs for forecasting applications. For example, the proposed hybrid SNR methods may be used to identify one or more data-driven and physics-motivated basis functions to characterize a plurality of well operating conditions represented by variations in bottom hole pressure. In particular, the proposed hybrid SNR methods may be used to determine fluid flow physics in the unconventional reservoir for horizontal multi-fractures based on routinely available data, such as rates and pressures, without making any mechanistic modeling assumptions for fracture and reservoir flow mechanisms. As a result, the proposed hybrid SNR methods may capture relevant non-linear process dynamics, resulting in a model that is parsimonious, simple to train and use, and fast to compute. Besides the natural system dynamics, the data-driven and physics-motivated basis function also includes the effect of external inputs (e.g., artificial lift, choke, etc.) in order to predict and manage production scenarios. The following description provides the disclosed methodology, potential applications, and several examples.

### Sparse Nonlinear Regression Using SINDy

Sparse identification of nonlinear dynamics (SINDy) is a machine learning (ML) approach that integrates sparsity-promoting methods and machine learning with nonlinear dynamical systems to discover governing physical equations based only on measurements. In some embodiments, SINDy is applied to discover fluid flow behavior in multiple fractured horizontal wells (MFHW) in unconventional reservoirs by establishing relationships between rates and bottom hole pressure just based on data. The generalized SINDy algorithm starts from the following simple formulation:

$$\frac{d}{d t} x ( t ) = f ( x ( t ) ) \qquad ( 1 )$$

where:
x(t)—state of the system at time t: x(t)=[x₁(t), x₂(t), . . . xₙ(t)]^{T}∈Rⁿ
ƒ—a nonlinear function

In some embodiments, the right-hand side nonlinear function ƒ(x(t)) describes the equation governing the evolution of the dynamical system. The key assumption in SINDy analysis is that the nonlinear function ƒ(x(t)) consists of only a few terms, making the governing equations sparse in a high-dimensional nonlinear system. This assumption holds true for many physical systems, Recent advances in sparse regression methods make this concept of parsimony favorable, since these algorithms may efficiently determine the right-hand side terms that are active in the regression library.

To determine the form of the nonlinear function ƒ(x(t)) based purely on data, the time-series measurements of the state x(t) and their derivatives with respect to time \dot{x}(t) may initially be collected as in Equation 2.

$$X = [ \begin{matrix}{x}^{T} ( {t}_{1} ) \\ {x}^{T} ( {t}_{2} ) \\ ⋮ \\ {x}^{T} ( {t}_{m} )\end{matrix} ] = [ \begin{matrix}{x}_{1} ( {t}_{1} ) & {x}_{2} ( {t}_{1} ) & … & {x}_{n} ( {t}_{1} ) \\ {x}_{1} ( {t}_{2} ) & {x}_{2} ( {t}_{2} ) & … & {x}_{n} ( {t}_{2} ) \\ ⋮ & ⋮ & ⋱ & ⋮ \\ {x}_{1} ( {t}_{m} ) & {x}_{2} ( {t}_{m} ) & … & {x}_{n} ( {t}_{m} )\end{matrix} ] \qquad ( 2 )$$

$$\dot{X} = [ \begin{matrix}{\dot{x}}^{T} ( {t}_{1} ) \\ {\dot{x}}^{T} ( {t}_{2} ) \\ ⋮ \\ {\dot{x}}^{T} ( {t}_{m} )\end{matrix} ] = [ \begin{matrix}{\dot{x}}_{1} ( {t}_{1} ) & {\dot{x}}_{2} ( {t}_{1} ) & … & {\dot{x}}_{n} ( {t}_{1} ) \\ {\dot{x}}_{1} ( {t}_{2} ) & {\dot{x}}_{2} ( {t}_{2} ) & … & {\dot{x}}_{n} ( {t}_{2} ) \\ ⋮ & ⋮ & ⋱ & ⋮ \\ {\dot{x}}_{1} ( {t}_{m} ) & {\dot{x}}_{2} ( {t}_{m} ) & … & {\dot{x}}_{n} ( {t}_{m} )\end{matrix} ]$$

where:
x(t)—state of the system at time t
\dot{x}(t)—derivatives of the state of the system with respect to time at time t

In some embodiments, an augmented library Θ(X), consisting of candidate nonlinear functions in each column, may be constructed. For example, Θ(X) may consist of constant, polynomial, logarithmic, exponential, and trigonometric functions as provided below.

$$θ ( X ) = [ \begin{matrix}\vert & \vert & \vert & \vert & \vert & \vert & \vert & \vert \\ 1 & X & {X}^{{P}_{2}} & {X}^{{P}_{3}} & … & sin ( X ) & cos ( X ) & … \\ \vert & \vert & \vert & \vert & \vert & \vert & \vert & \vert\end{matrix} ] \qquad ( 3 )$$

$${X}^{{P}_{2}} = [ \begin{matrix}{x}_{1}^{2} ( {t}_{1} ) & {x}_{1} ( {t}_{1} ) {x}_{2} ( {t}_{1} ) & … & {x}_{2}^{2} ( {t}_{1} ) & … & {x}_{n}^{2} ( {t}_{1} ) \\ {x}_{1}^{2} ( {t}_{2} ) & {x}_{1} ( {t}_{2} ) {x}_{2} ( {t}_{2} ) & … & {x}_{2}^{2} ( {t}_{2} ) & … & {x}_{n}^{2} ( {t}_{2} ) \\ ⋮ & ⋮ & ⋱ & ⋮ & ⋱ & ⋮ \\ {x}_{1}^{2} ( {t}_{m} ) & {x}_{1} ( {t}_{m} ) {x}_{2} ( {t}_{m} ) & … & {x}_{2}^{2} ( {t}_{m} ) & … & {x}_{n}^{2} ( {t}_{m} )\end{matrix} ]$$

where:
x(t)—state of the system at time t
Θ(X)—candidate nonlinear functions

Each column of Θ(X) is a candidate function for the right-hand side of Equation 1. According to the assumption of the sparsity of the governing physical equation, a sparse regression may be performed to determine a sparse vector of coefficients Ξ=[ξ₁, ξ₂, . . . , ξₙ] based on Equation 4.

$$\dot{x} ( t ) = θ ( x ) Ξ \qquad ( 4 )$$

where:
\dot{x}(t)—derivatives of the state of the system with respect to time at time t
Θ(X)—candidate nonlinear functions
   Ξ—a sparse vector of coefficients

### Formulation

In some embodiments, the goal of the disclosed hybrid SNR methods is to discover fluid flow dynamics in MFHWs by identifying relevant relationships between rates and pressures of different fluid phases. A simple formulation can be written as q=ƒ(BHP, t) in unconventional reservoirs. From diffusivity equations, standard fluid flow equations are usually represented by RNP expressions as function of reservoir properties, fluid PVT, well properties, and a time function depending on one or more selected flow regimes. The reservoir properties and/or fracture properties (in case of hydraulically fractured wells) are often unknown, and one of the key goals in RTA is to estimate these properties based on straight line analysis using knowledge about the characteristic equations. However, as described earlier, these estimates are based on several assumptions about mechanistic models, such as fractures and reservoir geometries, and involve manual steps that lead to highly interpretive results. The disclosed hybrid SNR methods may use an SINDy analysis in a data-driven workflow to derive equations that represent fluid flow for each well level based on routinely available data, such as rates and pressures. The SINDy analysis may efficiently identify a sparse model structure from data and bypass an intractable brute-force search through all possible models by leveraging the fact that many dynamical systems of the form based on Equation 1. The sparse model structure may be identified using a sparsity-promoting regression which penalizes the number of non-zero terms Ξ in a generalized linear system based on Equation 4.

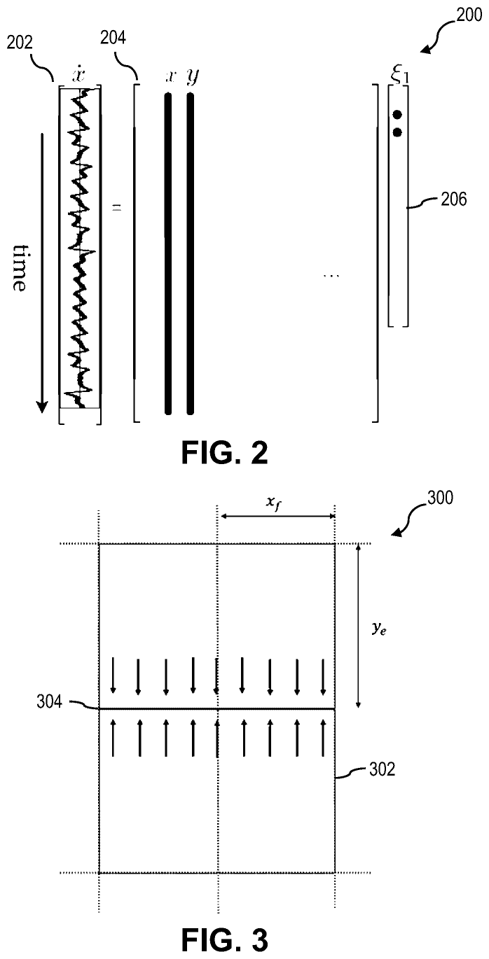

FIG. 2 illustrates a schematic of an example framework 200 of using a sparse identification of nonlinear dynamics (SINDy) regression to identify dominant and relevant terms in a dynamical model, in accordance with certain embodiments. Framework 200 may be implemented to solve a sparse optimization problem in finding a sparse vector of coefficients Ξ206 which optimally embeds a vector of derivatives \dot{x}(t) 202 of the state of a system with respect to time by recovering the dynamic model using the fewest terms in a regression library of the dynamical model as described in a matrix Θ(X) 204. Each column of matrix 204 represents a respective candidate nonlinear function with the respective column vector given by all possible time-series of d-th degree polynomials in the state x and state y of the system. For example, the regression library of the dynamical model may include a plurality of candidate nonlinear functions, such as one or more constant, polynomial, logarithmic, exponential, and trigonometric functions. The sparse vector of coefficients Ξ206 may be used to determine which terms are active in the regression library, such as one or more candidate nonlinear functions. Once the sparse vector of coefficients Ξ206 is computed, the framework 200 may be used to identify one or more governing equations in matrix 204 which are associated with one or more dominant and relevant terms in the dynamical model. Likewise, the discovered dynamical model may be used for future state prediction. However, the SINDy analysis may identify an inaccurate terms in the dynamical model when the plurality of candidate nonlinear functions in the regression library are non-orthogonal and/or overdetermined. In addition, the formulation described below is based on predicting an output quantity (e.g., rate normalized pressure) instead of its derivative, but the underlying concept of SINDy remains applicable.

In some embodiments, fractures in the data, the disclosed hybrid SNR methods may derive one or more key features which dominate the fluid flow dynamics in the dynamical model using inherent information about reservoirs. For example, the proposed hybrid SNR methods may implement a formulation to estimate RNP as a function of the regression library, such as a library of basis functions, which depend on time. This can be written as:

$$RNP = θ ( t ) Ξ \qquad ( 5 )$$

where:
RNP—rate normalized pressure
Θ(X)—candidate nonlinear functions
   Ξ—a sparse vector of coefficients

In some embodiments, the SINDy analysis may identify a sparse system with dominant features which have the most influence on the observed RNP data by using the library of basis functions which are time dependent based on the knowledge of physics of fluid flow in hydraulic fractures. The SINDy analysis may determine the sparse system using a sparse model with the fewest terms in the coefficients Ξ required to explain the observed RNP data. For example, the sparse model may be identified using a convex L1-norm regularized regression. Once the sparse model is obtained with the coefficients Ξ corresponding to selected features, the proposed hybrid SNR methods may be implemented to forecast RNP for any future time period. Furthermore, with the RNP estimate, the derived equation can be used to run rate forecast scenarios for any BHP profile provided.

In some embodiments, the proposed SNR methods may be used to implement an automated workflow to identify the rate-pressure relationship by incorporating physics based knowledge without having to make any assumptions beforehand about fractures and reservoirs,

### Physics Guided Basis Functions

In some embodiments, the SINDy analysis may fail to identify the correct sparse model with a poor choice of the candidate functions Θ(X) in the regression library of the dynamical model. The proposed hybrid SNR methods may include a physics guided feature library of basis functions which capture fundamental ideas behind fluid flow in hydraulically fractured unconventional reservoirs. The physics guided feature library may then be used in the SINDy formulation described above. The most suitable features may be identified based on the existing flowing conditions and regimes using an optimization routine.

### Wattenbarger's Type Curves

FIG. 3 illustrates a schematic of a conceptual model 300 of a vertical well with an infinite conductivity fracture 304 extending to the boundary of a closed reservoir 302, in accordance with certain embodiments. In some embodiments, extended periods of linear flow may be observed in many unconventional reservoirs, such as a gas reservoir with hydraulic fractures designed to extend to the drainage boundary of the well. The fracture 304 is assumed to be extended to the boundaries of the reservoir 302. Using solutions for constant rate (CR) and constant pressure (CP) inner boundary conditions for liquids, assuming the geometry (closed boundary) shown in FIG. 3, for a vertical well with a closed boundary, a transient linear flow and a boundary-dominated flow may be significant flow regimes in unconventional reservoirs. While the transient linear flow and the boundary-dominated flow are not always observed for unconventional reservoirs, because of various combinations of reservoir properties and fracture geometries, the solutions for the conceptual model 300 may serve as a useful reference point.

The Wattenbarger's type curve, which incorporates these flow regimes, is described as follows:

$${p}_{wD} = \frac{π}{2} ( \frac{{y}_{e}}{{x}_{f}} ) [ \frac{1}{3} + {( \frac{{x}_{f}}{{y}_{e}} )}^{2} {t}_{Dxf} ] - \frac{2}{{π}^{2}} ( \frac{{y}_{e}}{{x}_{f}} ) {\sum }_{n = 1}^{∞} ( \frac{1}{{n}^{2}} ) exp ( - {n}^{2} {{π}^{2} ( \frac{{x}_{f}}{{y}_{e}} )}^{2} {t}_{Dxf} ) \qquad ( 6 )$$

$${p}_{w D} = \frac{k h ( {p}_{i} - {p}_{w f} )}{141.2 q B μ}$$

$${t}_{D x f} = \frac{0.00633 k t}{{ϕμc}_{t} {x}_{f}^{2}}$$

where:
yₑ—distance from fracture to outer boundary, ft
x_{f}—fracture half-length, ft
k—formation permeability, mD
h—net formation thickness, ft
pᵢ—initial reservoir pressure, psi
q—flow rate, STB/d
B—formation volume factor, bbl/STB
μ—viscosity, cP
ϕ—porosity
cₜ—total compressibility, 1/psi
p_{wD}—dimensionless pressure
p_{wf}—flowing pressure, psi
t_{Dxf}—dimensionless time

For this case of the vertical well shown in FIG. 3, the transient linear flow is followed by boundary dominated flow. The element of symmetry may apply in certain cases to online production of MFHWs with equal fracture spacing and length, in which the reservoir beyond the fracture tips may not contribute significantly to flow. In this scenario an early period of transient linear flow to the fractures may be followed by depletion of the inter-fracture volume. The solutions given by Equation 6 have short-term approximations which are also the solutions for an infinite reservoir outer boundary. These approximations are given for a constant rate by Equation 7 and Equation 8, respectively:

$${p}_{w D} = \sqrt{π {t}_{Dxf}} \qquad ( 7 )$$

where:
p_{wD}—dimensionless pressure
t_{Dxf}—dimensionless time

Closed reservoir solutions can be approximated by the following equations for long times:

$${p}_{wD} = \frac{π}{2} ( \frac{{x}_{f}}{{y}_{e}} ) {t}_{Dxf} + \frac{π}{6} ( \frac{{y}_{e}}{{x}_{f}} ) \qquad ( 8 )$$

where:
yₑ—distance from fracture to outer boundary, ft
x_{f}—fracture half-length, ft
p_{wD}—dimensionless pressure
t_{Dxf}—dimensionless time

In some embodiments, similar equations may be represented for a single phase gas flow scheme using pseudo pressures to account for variable PVT properties with pressures in gas. p_{wD} is replaced with m_{wD} in Equation 9.

$${m}_{wD} = \frac{k h [ m ( {p}_{i} ) - m ( {p}_{w f} ) ]}{1424 {q}_{g} T} \qquad ( 9 )$$

$$m ( p ) = 2 {\int }_{{p}_{0}}^{p} \frac{p}{z μ} dp$$

where:
k—formation permeability, mD
h—net formation thickness, ft
pᵢ—initial reservoir pressure, psi
μ—viscosity, cP
m_{wD}—dimensionless pseudo-pressure
q_{g}—gas flow rate, MSCF/d
T—temperature, F
z—gas compressibility factor

In some embodiments, for a single phase flow in closed linear reservoir with fractures extending to the reservoir boundaries, a feature library may be proposed to express RNP. From the equations above, the linear combination of the following features based on Wattenbarger's equation as shown in Table 1 is sufficient to describe the fluid flow expressions in such a reservoir and fracture system. For example, the feature library may include a constant function. As another example, the feature library may include a linear function t in a boundary-dominated flow (BDF) period. As another example, the feature library may include an exponential function exp(−αt). α represents coefficients of time in exponential terms.

TABLE 1

| Features | Description |
|---|---|
| 1 | Constant |
| t | Major contribution at long time boundary- |
| | dominated flow (BDF) |
| exp(−αt) | For multiple α ∈ R (early transient linear |
| | flow), typically in range [10⁻³, 10⁻¹] based |
| | on the terms used to define α |

In some embodiments, all other parameters in the expression are constants corresponding to reservoir, fracture, and fluid properties. With the SINDy formulation proposed, the coefficients corresponding to each feature may represent a lumped quantity corresponding to the coefficients in the original equation. A case study is shown in a later section illustrating how SINDy can recover the original equation with reasonable accuracy preserving the information related to fracture and reservoir properties.

### Typical Flow Regime Analysis in MFHWs

In some embodiments, identification of flow regimes during flowback as well as early-time production is one of the most critical steps of an RTA workflow since the flow regime sequence dictates models to be used for obtaining reservoir and fracture property estimates and perform type curve analysis. Flow regimes in unconventional reservoirs with multiple-fractured horizontal wells are described by specific characteristics and patterns of flow both within the reservoir as well as within and toward hydraulic fractures, during the production life of a well. Typical sequence of flow regimes have been determined for long term production in MFHWs.

In some embodiments, the proposed hybrid SNR methods may be used to estimate a state, such as RNP and/or rate, of the dynamical system for production after the flowback period by using the SINDy formulation for production forecasting. Thus, identification of relevant and dominate flow regimes associated with the dynamical model plays an important role in understanding the flow regimes after flowback in order to propose candidate features for the feature library for production forecasting.

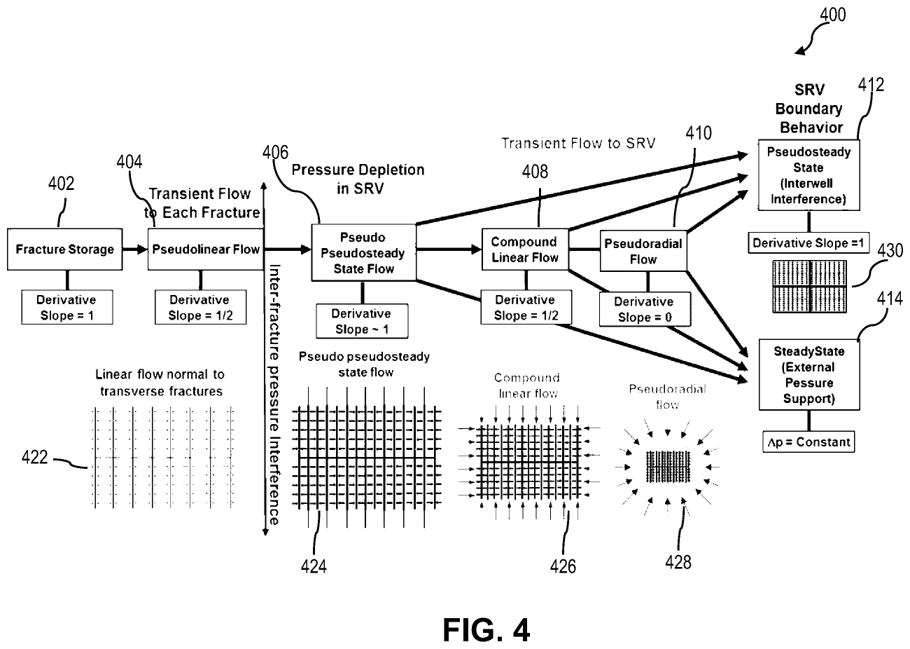

FIG. 4 illustrates a schematic of an example progression 400 of potential flow regimes in a multi-fractured horizontal well (MFHW), in accordance with certain embodiments. An expected progression 400 of flow regimes in a MFHW may include a fracture storage regime 402, a pseudolinear flow regime 404, a pseudo pseudosteady state flow regime 406, a compound linear flow regime 408, a pseudoradial flow regime 410, a pseudosteady state regime 412, a dual permeability or porosity regime, and a steady state regime 414. For example, in a diagnostic fracture injection test (DFIT), a relatively small volume of fluid is injected into the subsurface, creating a hydraulic fracture. After the end of injection, the pressure in the wellbore is monitored for hours or days. The pressure measurements are used to infer a plurality of key parameters for properties of the formation, such as leakoff coefficient, permeability, fracture closure pressure, and formation pressure, etc., for hydraulic fracture design and reservoir engineering.

In some embodiments, a fracture may not form at early times and the pressure behavior may be dominated by a fracture storage regime 402. The fracture storage regime 402 may be indicated by a unit-slope straight line with a 1.0 derivative slope on a log-log plot in which pressure changes linearly with time. The fracture storage regime 402 is associated with a wellbore storage effect immediately after a production start-up or shut-in. In some embodiments, the wellbore storage effect may be dominated by the compressibility and the volume of a fracturing fluid. For example, the compressibility is high for a gas-filled wellbore, and the wellbore storage effect may occur over a longer period of time. As another example, the compressibility is much lower for a liquid-filled wellbore, and the wellbore storage effect may dissipate more quickly. As another example, typically in oil wells, both gas and liquid are present within the wellbore and the liquid level changes after shut-in. Thus, fracture storage regime 402 may be affected by a changing liquid level as well as compressibility the liquid. In some embodiments, when a shut-in period following a fracture injection only extends to the end or slightly beyond closure, the equivalent constant rate pressure and derivative data may remain in fracture storage dominated flow regime 402 during the entire pressure falloff.

In some embodiments, the pressure behavior at early times may be dominated by a pseudolinear flow regime 404 at early times after closure when sufficient fracture half-length is created during the injection, provided the fracture after closure has essentially infinite conductivity. The pseudolinear flow regime 404 may include a linear flow 422 which shows the fracturing fluid flows to each fracture in a direction normal to the transverse fractures. The pseudolinear flow regime 404 is indicated by a 0.5 derivative slope on the log-log plot of RNP derivative versus time. In some embodiments, the pressure behavior may be dominated by a pseudo pseudosteady state flow regime 406 at middle times when inter-fracture interference increases with extended fractures, resulting in different fracture extension pressures and widths. A pseudo pseudosteady state flow 424 shows the fracturing fluid is filtered into the reservoir matrix after fracturing, reducing formation stress. The pseudo pseudosteady state flow regime 406 is indicated by an about 1.0 derivative slope on the log-log plot of RNP derivative versus time.

In some embodiments, the pressure behavior may be dominated by a compound linear flow regime 408 at middle times when the fractures fluid flows to SRV. The compound linear flow 426 during this period is perpendicular to the primary linear low. The compound linear flow regime 408 is indicated by an about 0.5 derivative slope on the log-log plot of RNP derivative versus time. In some embodiments, the pressure behavior may be dominated by a pseudoradial regime 410 at later times. If the fracture half-length is not very long, the pseudoradial flow 428 may appear during the extended test. Its pressure derivative may approach as a horizontal straight line at later times indicated by a 0.0 derivative slope on the log-log plot of RNP derivative versus time.

In some embodiments, the pressure behavior may be dominated by a pseudosteady state regime 412 at late times when the outer boundaries of the reservoir are all no flow boundaries. For example, the pseudosteady state regime 412 may occur when the reservoir boundaries are sealing faults. As another example, the pseudosteady state regime 412 may occur when nearby producing wells cause no flow boundaries to arise. The pseudosteady state flow 430 shows the reservoir behaves as a tank. The pressure throughout the reservoir decreases at the same, constant rate. In some embodiments, the pressure behavior may be dominated by a steady state regime 414 at late times when there is no change anywhere with time.

In some embodiments, the feature library may include a plurality of flow regimes at early, middle, and late times for various well configurations, such as a vertical well, a horizontal well, or a MFHW.

### Bilinear Flow

In some embodiments, the feature library may include a bilinear flow regime theoretically post flowback. When dimensionless fracture conductivity is less than 50, the pressure drop along the fracture is not negligible and intra-fracture transient linear flow occurs along with formation transient linear flow causing a bilinear flow regime. Bilinear flow regime is characterized by a quarter slope (0.25) on log-log RNP vs. time or log-log derivative plot for constant rate. The characteristic plot of RNP vs t^{0.25} gives a linear fit slope to estimate fracture conductivity provided the matrix permeability is known.

### Fracture Linear Flow

In some embodiments, the feature library may include a fracture linear flow (i.e., “linear flow”) regime at early times. A common flow regime analysis of a linear flow regime at early times may provide an estimate of the \sqrt{k}X_{ƒ}. In many wells, depending on fracture geometries and reservoir parameters, the linear flow regime can last up to several years. For oil wells, with constant rate, the linear flow equation to the fractures can be written in dimensionless form based on Equation 10.

$$\frac{{p}_{i} - {p}_{wf}}{{q}_{s c}} = \frac{4.06 B}{h} \sqrt{\frac{μ}{ϕ {c}_{t} k {X}_{f}^{2}}} \sqrt{t} \qquad ( 10 )$$

where:
pᵢ—initial reservoir pressure, psi
B—formation volume factor, bbl/STB
h—net formation thickness, ft
μ—viscosity, cP
ϕ—porosity
cₜ—total compressibility, 1/psi
k—formation permeability, mD
q_{sc}—flow rate at standard conditions, STB/d

In some embodiments, a similar expression can also be written for gas wells using pseudo pressures. This relation is characterized by a linear trend on a square root plot of RNP versus \sqrt{t}. The slope of this line is used to estimate the \sqrt{k}X_{ƒ} product.

### SRV Flow

In some embodiments, the feature library may include a SVR flow regime. The SRV flow regime exhibits behavior similar to the traditional pseudo steady state (PSS). The PSS flow regime does not describe the entire reservoir volume, but only includes stimulated rock volume (SRV), which is considered as the maximum practical volume for fluid production. The flow from beyond the SRV will be minor and may take from years to decades to manifest itself. The SRV flow regime is thus characterized by unit slope on log-log RNP vs. time plot or log-log derivative plot.

In some embodiments, based on the conventional PSS concepts, a straight-line analysis may be used on this portion of the data to estimate a ‘drainage area’ (essentially the SRV). For oil, the slope of straight line on RNP vs. material balance time is given by Equation 11.

$$m = 0.234 \frac{B}{ϕ {c}_{t} h A} \qquad ( 11 )$$

where:
B—formation volume factor, bbl/STB
ϕ—porosity
cₜ—total compressibility, 1/psi
h—net formation thickness, ft
k—formation permeability, mD
A—cross-sectional flow area, ft²

Similarly, for gas the slope is given by Equation 12.

$$m = 2348 \frac{{TP}_{s c}}{ϕ {c}_{ti} h {μ}_{g i} A {T}_{s c}} \qquad ( 12 )$$

where:
ϕ—porosity
h—net formation thickness, ft
P_{sc}—pressure at standard conditions, psi
T_{sc}—temperature at standard conditions, psi
cₜᵢ—initial total compressibility, 1/psi

### Compound Linear Flow

In some embodiments, the feature library may include a compound linear flow regime. During later stages of well production, after fracture interference, and possibly a period of between-fracture depletion, a second period of formation transient linear flow may occur. This is referred to as compound linear flow or late linear flow. Analysis of compound linear flow yields L_{w}\sqrt{k}, where L_{W} is effective producing well half-length, or the half-length of the well that is effectively stimulated (in contact with the reservoir). The constant rate solution may be applied to the linear flow plot to yield L_{w}\sqrt{k}. For single-phase flow of undersaturated oil during compound linear flow is provided based on Equation 13.

$${L}_{w} \sqrt{k} = \frac{4.064 {μ}_{o i} {B}_{o i}}{{m}_{{LFP}_{CR}} h} {( \frac{1}{ϕ {μ}_{0} {c}_{t}} )}_{i}^{0.5} \qquad ( 13 )$$

where:
ϕ—porosity
h—net formation thickness, ft
cₜ—total compressibility, 1/psi
μₒᵢ—initial oil viscosity, cP
Bₒᵢ—initial oil formation volume factor, rb/STB
m_{LFP_CR}—slope of linear flow for contacted reservoir

### Infinite Acting Radial Flow

In some embodiments, the feature library may include an infinite acting radial flow regime. In theory, if enough time passed, the system may reach an infinite acting radial flow (IARF) regime. In unconventional reservoirs, this can occur hundreds to thousands of years into production. However, this is very unlikely to happen as, by this time, the production would become infinitesimal, and the well would be long abandoned. Hence, the IARF regime is not considered as a candidate feature.

In some embodiments, based on the above listed flow regimes that are most commonly considered and analyzed in MFHWs, the feature library may include the following list of features based on characteristic flow equations as shown in Table 2 to be considered as candidate functions.

TABLE 2

| Features based on typical | |
|---|---|
| flow regime analysis | Flow Regimes |
| t^{0.25} | Bilinear flow |
| t^{0.5} | Linear flow to individual fractures |
| t | SRV flow/Pseudo steady state flow |
| t^{0.5} | Compound linear flow |

### Complex Flow Regimes

In some embodiments, the feature library may include additional features associated with other complex flow regimes which are hard to capture through conventional straight-line analysis or do not show the expected characteristic behavior. In the field, the fracture growth and distribution in a well may be quite complex such that it is hard to model using analytical formulations.

In some embodiments, transitional flow regimes (radial/elliptical) are observed during inter-fracture flow. After a certain period of initial production when flow to each fracture is independent, the pressure distributions near the fractures begin to interfere. Both the normalized pressure and pressure derivative begin to deviate (slightly) upwards from the expected linear flow half-slope trend, where this represents a loss of productivity for the well. This transitionary flow period is represented by a nonlinear trend with continuously changing slope until it completely transitions to SRV flow.

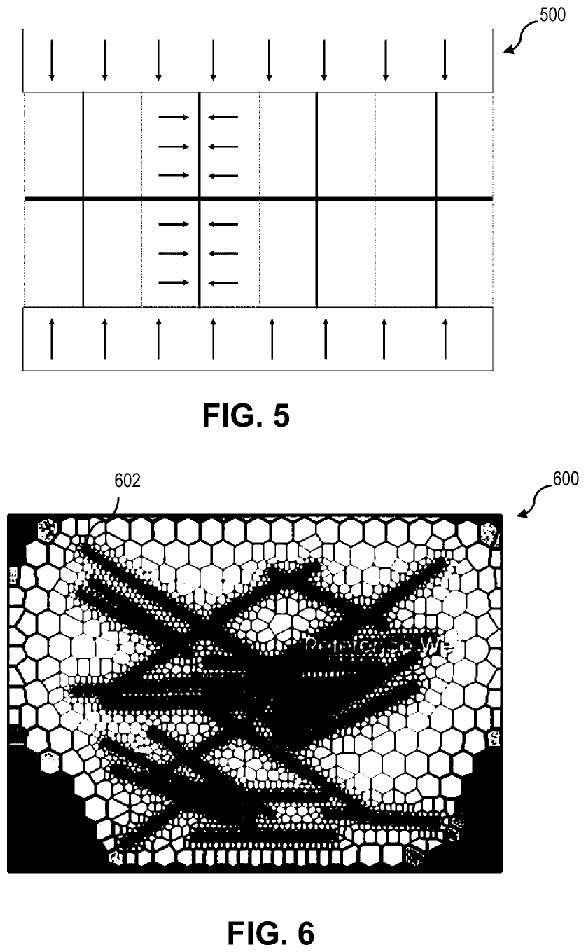

FIG. 5 illustrates a schematic of a conceptual model 500 of a simultaneous inter-fracture flow and boundary dominated flow, in accordance with certain embodiments. In very low-permeability (shale) reservoirs, a pure depletion signature may be observed (unit slope on log-log RNP/RNP′ plot). The pure depletion signature may be attributed to lack of inflow of reservoir fluid from outside of the stimulated region to inter-fracture region, as depicted in FIG. 5. Similarly, many flow regimes may coexist in a complex fracture system, which is often the case due to reservoir heterogeneity and completion effectiveness. When multiple flow regimes coexist, the diagnostics plots do not show a clear signature of a particular flow regime.

FIG. 6 illustrates a schematic of a conceptual model of a complex fracture network 600, in accordance with certain embodiments. The complex fracture network 600 may include a plurality of fractures 602 with a complex fracture geometry. For example, the fractures 602 are not spaced uniformly and have unequal lengths, etc. A linear flow regime is not sufficient to characterize the dynamical flow associated with the complex fracture network 600. As a result, the pressure and flow rate behaviors observed in unconventional reservoirs that do not exhibit linear flow regime may be interpreted. Multiple flow regimes (sub-linear, linear, sub-radial) may be diagnosed based on the standard log-log plot.

In some embodiments, a multi-fractured horizontal well in a fractured formation can be compared to a fractured well (with the fracture length equal to the sum of all initially connected high conductivity fractures) that drains a reservoir with a flowing area A, that is perpendicular to the flow and changes with distance according to the power law:

$$A = {X}_{f} h {r}_{D}^{2 δ - 1} \qquad ( 14 )$$

where:
h—net formation thickness, ft
δ—half flow dimension
x_{f}—fracture half length, ft
r_{D}—dimensionless wellbore radius
A—flowing area, ft\hat{ }2

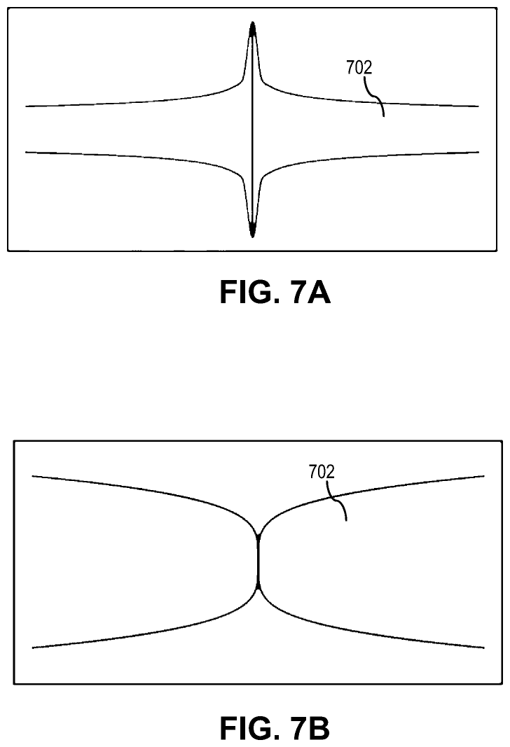

FIGS. 7A and 7B illustrate plots illustrating examples of sub-linear and sub-radial flow regimes, respectively, in accordance with certain embodiments. In the case of δ=0.5 the flow regime is linear and the flowing area becomes constant with respect to the distance to the fracture area, i.e. the case reduces to the channel geometry. Also, the case of δ=1 is a classical radial flow, and δ=0 corresponds to the pseudo steady state (PSS). This generalized model includes the cases with flow area 702 decreasing with the distance from the fracture (sub-linear flow, values of 0<δ<0.5, as shown in FIG. 7A), and flow area 702 increasing with the distance from the fracture (sub-radial flow, values of 0.5<δ<1, as shown in FIG. 7B).

In some embodiments, during such complex flow regimes, the pressure and pressure derivative are functions of the time raised to the power (1−δ), which can be diagnosed on a log-log plot. The sub-linear case might represent a MFHW in a densely fractured reservoir, when the areas drained by each fracture reduce with distance because of fractures' interference. On the other hand, the sub-radial case might correspond to a network of fractures of both high and low conductivity, the latter having a drainage area that increases with distance in a more pronounced way. An example of sub-linear and sub-radial flow regimes may be found in Table 3.

TABLE 3

| Features based on complex fractures | Interpretation |
|---|---|
| t^{1-δ} | δ ∈ (0, 0.5) for sublinear flow |
| | δ ∈ (0.5, 1) for subradial flow |

In some embodiments, the proposed hybrid SNR methods may investigate all possibilities of feature space which satisfy relationships between rates and pressures for as many possibilities of reservoir and fracture flow mechanisms and configurations. The optimization algorithm may be used to identify the best possible combination of features which best describes the data at the well level. Each well can have a different set of characteristics which describe the fluid flow such as effectiveness of completion, well spacing, timing of well completion, associated reservoir properties, etc. Thus, instead of making any mechanistic assumptions on fractures and reservoirs, the data is used to determine the characteristic relations.

In some embodiments, based on the descriptions about various flow regimes as summarized above, the relationship to be characterized using the hybrid SINDy approach is shown in Equation 15. The goal is to find sparse combinations of aᵢ and bⱼ coefficients that best explain the relationship.

$$\begin{matrix}RNP = {\sum }_{i} {a}_{i} {t}^{m} + {\sum }_{j} {b}_{j} {e}^{- nt} , & m ∈ [ 0 , 1 ] and n ∈ [ 1 {0}^{- 3} , 1 {0}^{- 1} ]\end{matrix} \qquad ( 15 )$$

where:
RNP—rate normalized pressure
aᵢ—coefficients
bᵢ—coefficients
   t—time

### Methods for Production Forecasting

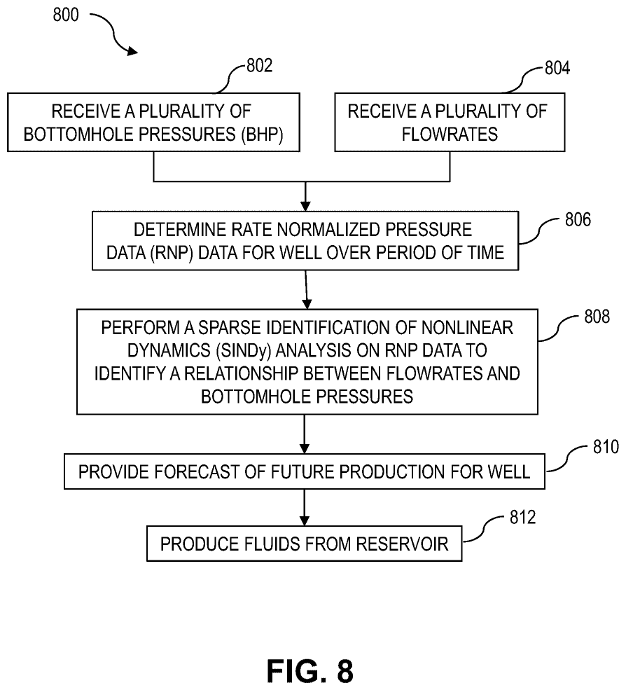

FIGS. 8-10 and 40 depict various methods in accordance with the present techniques. While the various blocks in FIGS. 8, 9, 10, and 40 are presented and described sequentially, some or all of the blocks may be executed in different orders, may be combined or omitted, and some or all of the blocks may be executed in parallel. Furthermore, the blocks may be performed actively or passively.

FIG. 8 illustrates a flow chart of an example method 800 of forecasting production of a well penetrating a reservoir in a subterranean formation, in accordance with one or more embodiments. At block 802, the method 800 includes receiving a plurality of bottomhole pressures (BHPs) for a well. At block 804, the method 800 includes receiving a plurality of flowrates for the well. These flowrates may be liquid flowrates, oil flowrates, and/or gas flowrates. At block 806, the method 800 includes determining rate normalized pressure (RNP) data for the well over a period of time based on the bottomhole pressures and flowrates. At block 808, the method 800 includes performing a sparse identification of nonlinear dynamics (SINDy) analysis on the RNP data to identify a relationship between flowrate and bottomhole pressure for the well. As discussed at length above, the SINDy analysis is based on physics and/or data-driven features. These physics and/or data-driven features may include any of the flow regimes described above. For example, the physics features may include a bilinear flow regime; a fracture linear flow regime; one or both of a stimulated rock volume (SRV) flow regime or pseudo steady state flow regime; a compound linear flow regime; and/or one or both of a sub-linear flow regime or a sub-radial flow regime. At block 810, the method 800 includes providing a forecast of future production for the well based on the identified relationship between flowrate and bottomhole pressure for the well. At block 812, the method 800 includes producing fluids from the reservoir based, at least in part, on the forecast of future production.

Particular embodiments may repeat one or more steps of the method of FIG. 8, where appropriate. Although this disclosure describes and illustrates particular steps of the method of FIG. 8 as occurring in a particular order, this disclosure contemplates any suitable steps of the method of FIG. 8 occurring in any suitable order. Moreover, although this disclosure describes and illustrates an example method to perform the hybrid SNR workflow to provide forecast of production of the well penetrating the reservoir in the subterranean formation, including the particular steps of the method of FIG. 8, this disclosure contemplates any suitable method including any suitable steps, which may include all, some, or none of the steps of the method of FIG. 8, where appropriate. In some embodiments, although this disclosure describes and illustrates particular components, devices, or systems carrying out particular steps of the method of FIG. 8, this disclosure contemplates any suitable combination of any suitable components, devices, or systems carrying out any suitable steps of the method of FIG. 8.

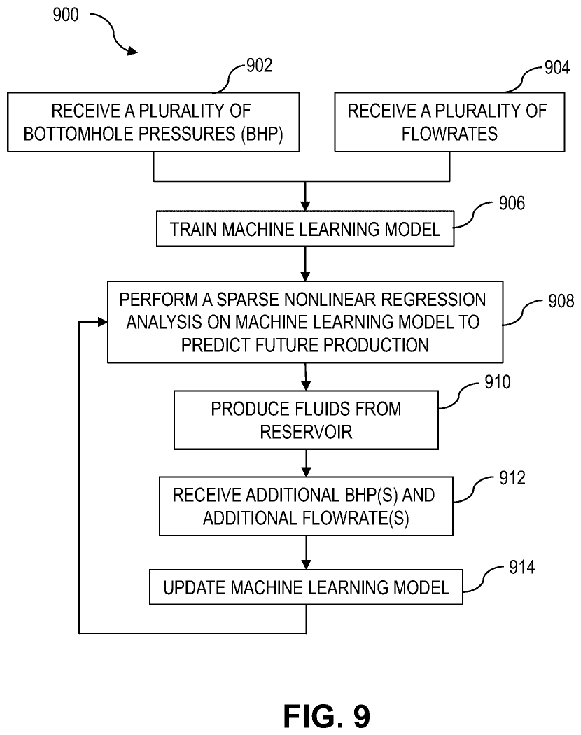

FIG. 9 illustrates a flow chart of another method 900 of forecasting production of a well penetrating a reservoir in a subterranean formation, in accordance with one or more embodiments. At block 902, the method 900 includes receiving a plurality of bottomhole pressures (BHPs) for a well. At block 904, the method 900 includes receiving a plurality of flowrates for the well. These flowrates may be liquid flowrates, oil flowrates, and/or gas flowrates. At block 906, the method 900 includes training a machine learning model based on the bottomhole pressures and the flowrates for the well. At block 908, the method 900 includes performing a sparse nonlinear regression analysis on the machine learning model to predict future production of the well, wherein the regression analysis is based on a plurality of physics and/or data-driven features. The plurality of physics and/or data-driven features may include any of the flow regimes described above. For example, the physics and/or data-driven features may include a bilinear flow regime; a fracture linear flow regime; one or both of a stimulated rock volume (SRV) flow regime or pseudo steady state flow regime; a compound linear flow regime; and/or one or both of a sub-linear flow regime or a sub-radial flow regime. The sparse nonlinear regression analysis may be a sparse identification of nonlinear dynamics (SINDy) analysis, as described above. At block 910, the method 900 includes producing fluids from the reservoir based, at least in part, on the predicted future production of the well. At block 912, the method 900 may include, during or after producing the fluids, receiving one or more additional bottomhole pressures for the well and one or more additional flowrates for the well. At block 914, the method 900 may include updating the machine learning model based on the additional bottomhole pressures and flowrates for the well. Blocks 908-914, in whole or in part, may be performed again based on the updated machine learning model. For example, at block 908, the method 900 may include performing the sparse nonlinear regression analysis on the updated machine learning model to provide an updated prediction of the future production for the well.

Particular embodiments may repeat one or more steps of the method of FIG. 9, where appropriate. Although this disclosure describes and illustrates particular steps of the method of FIG. 9 as occurring in a particular order, this disclosure contemplates any suitable steps of the method of FIG. 9 occurring in any suitable order. Moreover, although this disclosure describes and illustrates an example method to perform the hybrid SNR workflow to provide forecast of production of the well penetrating the reservoir in the subterranean formation, including the particular steps of the method of FIG. 9, this disclosure contemplates any suitable method including any suitable steps, which may include all, some, or none of the steps of the method of FIG. 9, where appropriate. In some embodiments, although this disclosure describes and illustrates particular components, devices, or systems carrying out particular steps of the method of FIG. 9, this disclosure contemplates any suitable combination of any suitable components, devices, or systems carrying out any suitable steps of the method of FIG. 9.

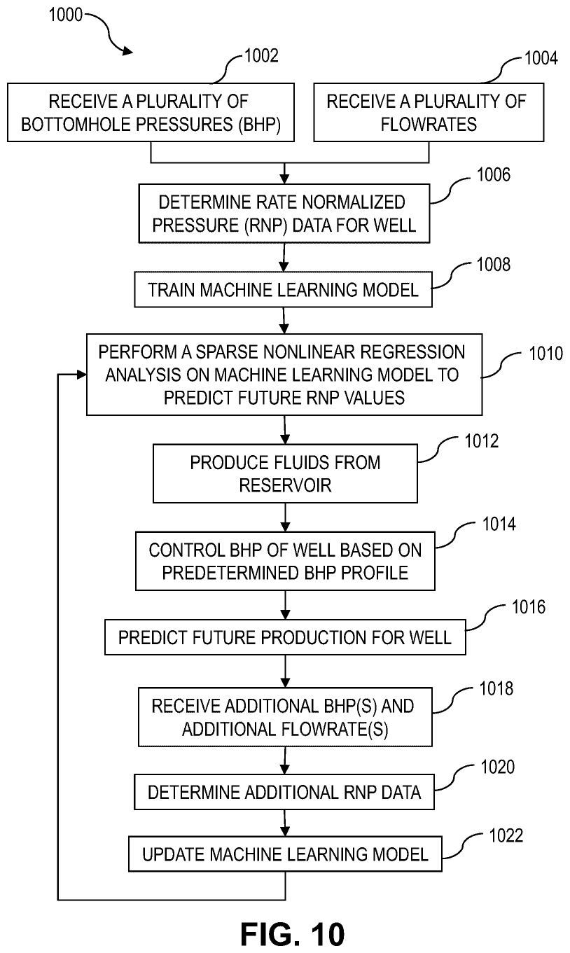

FIG. 10 is a flow chart of a method 1000 of forecasting production of a well penetrating a reservoir in a subterranean formation, in accordance with one or more embodiments. At block 1002, the method 1000 includes receiving a plurality of bottomhole pressures for the well. At block 1004, the method 1000 includes receiving a plurality of flowrates for the well. These flowrates may be liquid flowrates, oil flowrates, and/or gas flowrates. At block 1006, the method 1000 includes determining rate normalized pressure (RNP) data for the well based on the bottomhole pressures and flowrates. At block 1008, the method 1000 includes training a machine learning model based on the RNP data for the well. At block 1010, the method 1000 includes performing a sparse nonlinear regression analysis on the machine learning model to predict future RNP values for the well, wherein the regression analysis is based on physics and/or data-driven features. These physics and/or data-driven features may include any of the flow regimes described above. For example, the physics and/or data-driven features may include a bilinear flow regime; a fracture linear flow regime; one or both of a stimulated rock volume (SRV) flow regime or pseudo steady state flow regime; a compound linear flow regime; and/or one or both of a sub-linear flow regime or a sub-radial flow regime. The sparse nonlinear regression analysis may be a sparse identification of nonlinear dynamics (SINDy) analysis, as described above. At block 1012, the method 1000 includes producing fluids from the reservoir based, at least in part, on the future RNP values for the well. At block 1014, the method 1000 may include controlling a bottomhole pressure of the well based on a predetermined bottomhole pressure profile. At block 1016, the method 1000 may include predicting future production rates for the well based on the predicted future RNP values and the predetermined bottomhole pressure profile. At block 1018, the method 1000 may include, during or after producing the fluids, receiving one or more additional bottomhole pressures for the well and one or more additional flowrates for the well. At block 1020, the method 1000 may include determining additional RNP data for the well based on the additional bottomhole pressures and additional flowrates. At block 1022, the method 1000 may include updating the machine learning model based on the additional RNP data for the well. Blocks 1010-1022, in whole or in part, may be performed again on the updated machine learning model. For example, at block 1010, the method 1000 may include performing the sparse nonlinear regression analysis on the updated machine learning model to predict additional future RNP values for the well.

Particular embodiments may repeat one or more steps of the method of FIG. 10, where appropriate. Although this disclosure describes and illustrates particular steps of the method of FIG. 10 as occurring in a particular order, this disclosure contemplates any suitable steps of the method of FIG. 10 occurring in any suitable order. Moreover, although this disclosure describes and illustrates an example method to perform the hybrid SNR workflow to provide forecast of production of the well penetrating the reservoir in the subterranean formation, including the particular steps of the method of FIG. 10, this disclosure contemplates any suitable method including any suitable steps, which may include all, some, or none of the steps of the method of FIG. 10, where appropriate. In some embodiments, although this disclosure describes and illustrates particular components, devices, or systems carrying out particular steps of the method of FIG. 10, this disclosure contemplates any suitable combination of any suitable components, devices, or systems carrying out any suitable steps of the method of FIG. 10.

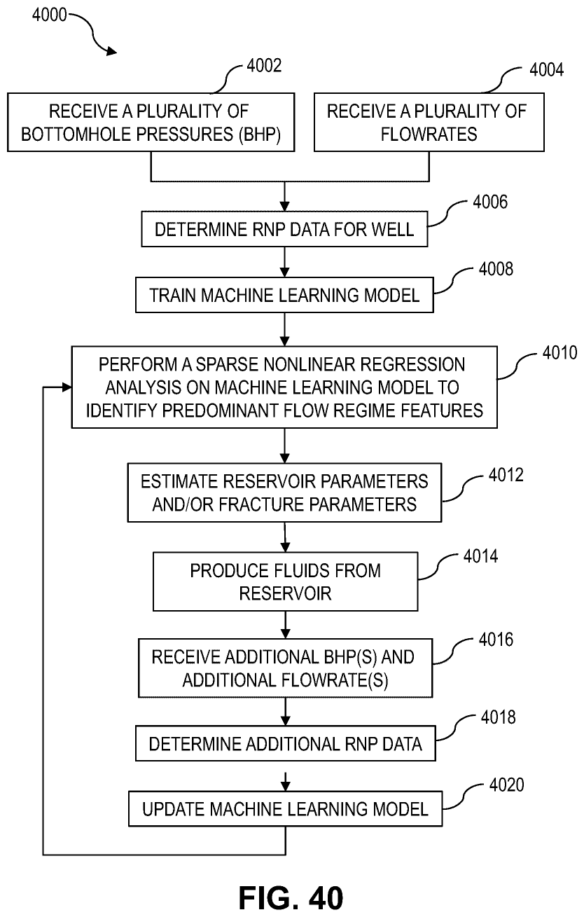

FIG. 40 is a flow chart of a method 4000 of forecasting production of a well penetrating a reservoir in a subterranean formation, in accordance with one or more embodiments. At block 4002, the method 4000 includes receiving a plurality of bottomhole pressures for the well. At block 4004, the method 4000 includes receiving a plurality of flowrates for the well. These flowrates may be liquid flowrates, oil flowrates, and/or gas flowrates. At block 4006, the method 4000 includes determining rate normalized pressure (RNP) data for the well based on the bottomhole pressures and flowrates. At block 4008, the method 4000 includes training a machine learning model based on the RNP data for the well. At block 4010, the method 4000 includes performing a sparse nonlinear regression analysis on the machine learning model to identify predominant flow regime features governing a relationship between flowrate and bottomhole pressure for the well. The predominant flow regime features may be one or more flow regimes that dominate the data based on the results of the regression analysis, selected from the group of flow regimes including, for example, a bilinear flow regime; a fracture linear flow regime; one or both of a stimulated rock volume (SRV) flow regime or pseudo steady state flow regime; a compound linear flow regime; and/or one or both of a sub-linear flow regime or a sub-radial flow regime. The sparse nonlinear regression analysis may be a sparse identification of nonlinear dynamics (SINDy) analysis, as described above. At block 4012, the method 4000 includes estimating reservoir parameters, fracture parameters, or both based on the identified predominant flow regime features. At block 4014, the method 4000 includes producing fluids from the reservoir based, at least in part, on the estimated reservoir parameters, fracture parameters, or both. At block 4016, the method 4000 may include, during or after producing the fluids, receiving one or more additional bottomhole pressures for the well and one or more additional flowrates for the well. At block 4018, the method 4000 may include determining additional RNP data for the well based on the additional bottomhole pressures and additional flowrates. At block 4020, the method 4000 may include updating the machine learning model based on the additional RNP data for the well. Blocks 4010-4020, in whole or in part, may be performed again on the updated machine learning model. For example, at block 4010, the method 4000 may include performing the sparse nonlinear regression analysis on the updated machine learning model to continue identifying predominant flow regime features for the well.

Particular embodiments may repeat one or more steps of the method of FIG. 40, where appropriate. Although this disclosure describes and illustrates particular steps of the method of FIG. 40 as occurring in a particular order, this disclosure contemplates any suitable steps of the method of FIG. 40 occurring in any suitable order. Moreover, although this disclosure describes and illustrates an example method to perform the hybrid SNR workflow to provide forecast of production of the well penetrating the reservoir in the subterranean formation, including the particular steps of the method of FIG. 40, this disclosure contemplates any suitable method including any suitable steps, which may include all, some, or none of the steps of the method of FIG. 40, where appropriate. In some embodiments, although this disclosure describes and illustrates particular components, devices, or systems carrying out particular steps of the method of FIG. 40, this disclosure contemplates any suitable combination of any suitable components, devices, or systems carrying out any suitable steps of the method of FIG. 40.

To demonstrate the benefits of the hybrid SNR methods discussed above, the hybrid SNR methods are applied to several field cases in the following Examples 1-8.

### Hardware Implementation

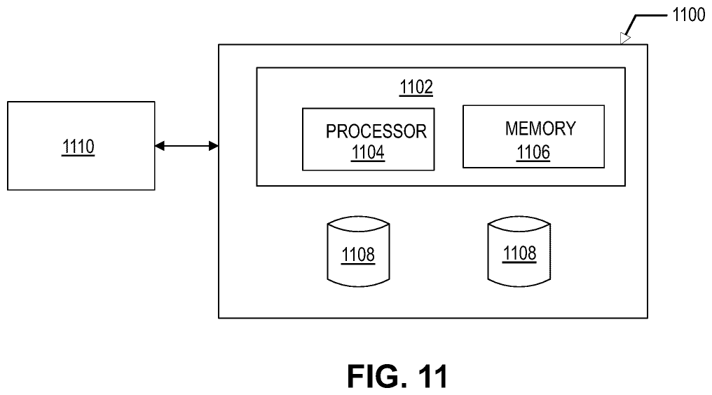

FIG. 11 illustrates a block diagram of an exemplary control unit 1100 in accordance with some embodiments of the present disclosure. In certain example embodiments, control unit 1100 may be configured to create and maintain one or more databases 1108 that include information concerning one or more reservoirs or reservoir models. In certain example embodiments, control unit 1100 is configured to use information from database(s) 1108 to train one or many machine learning algorithms, including, but not limited to, artificial neural network, random forest, gradient boosting, support vector machine, or kernel density estimator. In some embodiments, control system 1102 may include one more processors, such as processor 1104. Processor 1104 may include, for example, a microprocessor, microcontroller, digital signal processor (DSP), application specific integrated circuit (ASIC), or any other digital or analog circuitry configured to interpret and/or execute program instructions and/or process data. In some embodiments, processor 1104 may be communicatively coupled to memory 1106. Processor 1104 may be configured to interpret and/or execute non-transitory program instructions and/or data stored in memory 1106. Program instructions or data may constitute portions of software for carrying out production forecasts, as described herein. Memory 1106 may include any system, device, or apparatus configured to hold and/or house one or more memory modules; for example, memory 1106 may include read-only memory, random access memory, solid state memory, or disk-based memory. Each memory module may include any system, device or apparatus configured to retain program instructions and/or data for a period of time (e.g., computer-readable non-transitory media).

Although control unit 1100 is illustrated as including two databases 1108, control unit 1100 may contain any suitable number of databases and machine learning algorithms. Control unit 1100 may be communicatively coupled to one or more displays 1110 such that information processed by control system 1102 may be conveyed to operators at or near the well or may be displayed at a location offsite.

Modifications, additions, or omissions may be made to FIG. 11 without departing from the scope of the present disclosure. For example, FIG. 11 shows a particular configuration of components for control unit 1100. However, any suitable configurations of components may be used. For example, components of control unit 1100 may be implemented either as physical or logical components. Furthermore, in some embodiments, functionality associated with components of control unit 1100 may be implemented in special purpose circuits or components. In other embodiments, functionality associated with components of control unit 1100 may be implemented in a general purpose circuit or components of a general purpose circuit. For example, components of control unit 1100 may be implemented by computer program instructions.

### Case Studies

To facilitate a better understanding of the present disclosure, the following examples of certain aspects of preferred embodiments are given. The following examples are not the only examples that could be given according to the present disclosure and are not intended to limit the scope of the disclosure or claims. To demonstrate the benefits of the proposed hybrid SNR methods discussed above, the workflows were applied to several field cases in the following Examples 1-8.

In some embodiments, the proposed hybrid SNR methods may be implemented to identify one or more relevant flow equations in single phase MFHWs flowing under a variety of reservoir geometries and fracture configurations. The identified one or more flow equations are then used to perform production forecasting for a given bottomhole pressure profile.

### Example 1—Constant Oil Rate—Wattenbarger Model

In this example, a synthetic case may be generated using Wattenbarger's closed reservoir boundary equation (Equation 6) for fractures extending to the reservoir boundary in a single-phase oil reservoir. A hybrid SNR method may be implemented to generate a synthetic bottomhole pressure profile for a provided constant rate based on a plurality of input parameters and the Wattenbarger model. An example of the plurality of input parameters for synthetic data using Wattenbarger model may be shown in Table 4.

TABLE 4

| pᵢ | 5000 | psi |
|---|---|---|
| q | 100 | STB/d |
| B | 1.02 | bbl/STB |
| μ | 0.3 | |
| yₑ | 500 | ft |
| x_{f} | 500 | ft |
| ϕ | 0.1 | |
| cₜ | 7.8 * 10⁻⁶ | psi⁻¹ |
| k | 0.001 | mD |
| h | 100 | ft |

| | |
|---|---|
| num fracs | 10 |

In some embodiments, using the element of symmetry, the results below are shown for a single fracture that is analogous to the representation by Wattenbarger. The hybrid SNR method may use the SINDy formulation to determine a first model to predict RNP as stated above for the proposed time-dependent features in Table 1. For the SINDy formation, 52 candidate features are used. The first 50 features correspond to the exponential terms representing primarily the initial transient flow conditions taken at evenly sampled coefficients (α in Table 1) between 0.001 and 0.1 on a log scale. The 51^{st} feature is a constant and the 52^{nd} feature corresponds to a linear time feature that dominates during boundary dominated flow (BDF). In some embodiments, the first model may be run for multiple durations (1000 days, 5000 days and 10000 days) to generate different datasets. For each case, 75% of the data may be used for training the first model and the remaining 25% may be used for model validation.

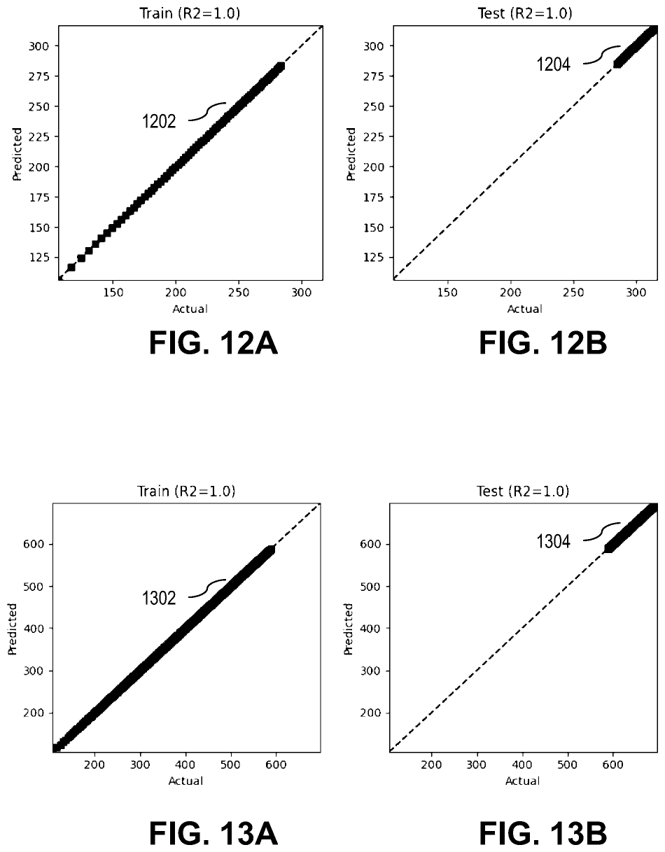

FIGS. 12A and 12B illustrate plots of predicted vs. actual rate normalized pressure (RNP) data for a machine learning training portion and a test portion, respectively, taken from a 1,000 day dataset, in accordance with certain embodiments. The hybrid SNR method may be used to train the first model in order to predict RNP estimates by identifying one or more relevant terms from the 52 candidate features in the candidate feature library. FIG. 12A shows a good consistency 1202 with a R-squared (R2) value of 1.0 in a cross plot of the predict RNP values and the actual RNP data in the machine learning training portion. FIG. 12B shows a good consistency 1204 with an R2 value of 1.0 in a cross plot of the predict RNP values and the actual RNP data in the test portion. The consistency between the predict RNP values and the actual RNP data in the machine learning training portion and the test portion indicates that the first model is accurate to predict the RNP estimates. Likewise, for any operational scenario with a bottomhole pressure profile, the first model may be used to accurately predict oil rate estimates. An R2 value shows how well the model predicts the outcome of the dependent variable. An R2 value of 0 means that the model explains or predicts 0% of the relationship between the dependent and independent variables. An R2 value of 1.0 means that the model explains or predicts 100% of the relationship between the dependent and independent variables.

FIGS. 13A and 13B illustrate plots of predicted vs. actual RNP data for a machine learning training portion and a test portion, respectively, taken from a 5,000 day dataset, in accordance with certain embodiments. The proposed hybrid SNR method may be used to train the first model to predict RNP estimates by identifying one or more relevant terms from the 52 candidate features in the candidate feature library. FIG. 13A shows a good consistency 1302 with an R2 value of 1.0 in a cross plot of the predict RNP values and the actual RNP data in the machine learning training portion. FIG. 13B shows a good consistency 1304 with an R2 value of 1.0 in a cross plot of the predict RNP values and the actual RNP data in the test portion. The consistency between the predict RNP values and the actual RNP data in the machine learning training portion and the test portion indicates that the first model is accurate to predict the RNP estimates. Likewise, for any operational scenario with a bottomhole pressure profile, the first model may be used to accurately predict oil rate estimates.

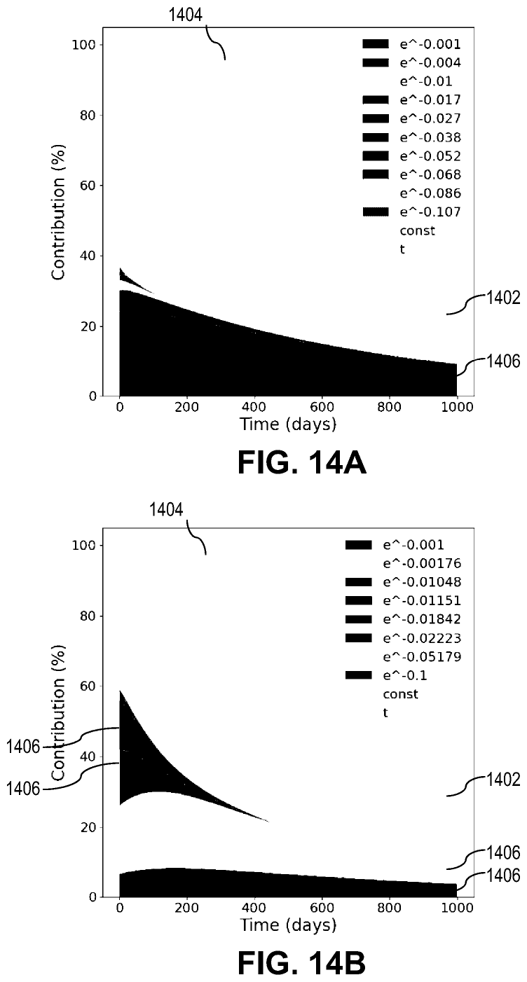

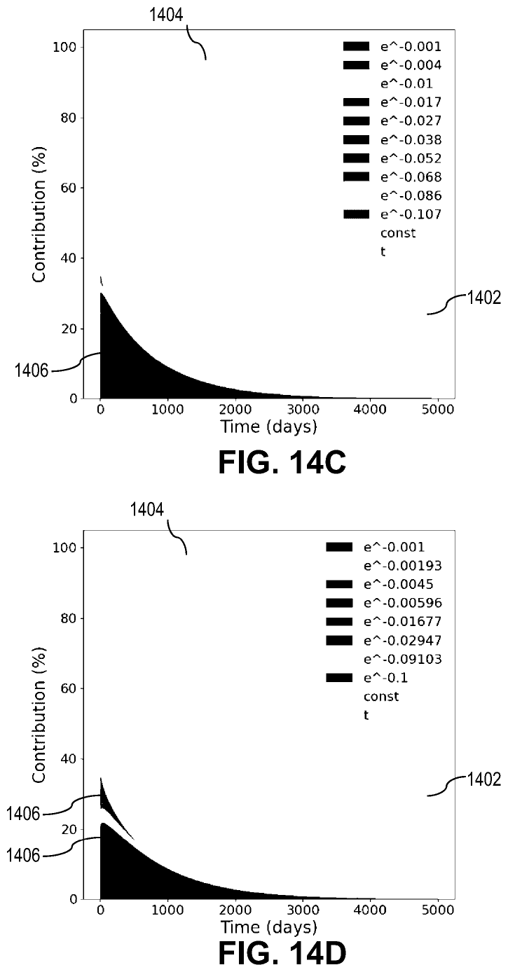

FIGS. 14A-14D illustrate plots showing importance of various coefficients with time for actual data for a 1,000 day dataset (FIG. 14A), predicted data for a 1,000 day dataset (FIG. 14B), actual data for a 5,000 day dataset (FIG. 14C), and predicted data for a 5,000 day dataset (FIG. 14D), in accordance with certain embodiments. In some embodiments, the hybrid SNR method may be used to induce sparsity on the candidate feature library and determine one or more coefficients associated with one or more relevant features from the candidate feature library. Furthermore, the proposed hybrid SNR method may determine if the one or more coefficients corresponding to the selected basis functions closely represent the true underlying equation.

FIGS. 14A and 14B show the selected features (out of a total of 52 in this case) and their contributions with time for both the truth case and the model predicted scenarios for the 1,000 day dataset. The first model has successfully eliminated several candidate basis functions and identified ten features to achieve an accurate match to the actual data. The ten features include a constant feature 1402, a linear time feature 1404, and eight exponential features 1406. The exponential features 1406 are the short transients that may not be of primary interest. Further, since exact a values for the exponential features may not be proposed (due to the unknown values of parameters contributing to a), the coefficients of these exponential features 1406 predicted by the optimization algorithm should be such that the linear combination of these features selected will closely represent the actual features. However, the coefficients of the constant feature 1402 and the coefficients of the linear time feature 1404 may be directly correlated in FIG. 14A and FIG. 14B since those are the exact features used as in the actual analytical equation.

FIGS. 14C and 14D show the selected features (out of a total of 52 in this case) and their contributions with time for both the truth case and the model predicted scenarios for the 5,000 day dataset. The first model has successfully eliminated several candidate basis functions and identified ten features to achieve an accurate match. The ten features include a constant feature 1402, a linear time feature 1404, and eight exponential features 1406. The exponential features 1406 are the short transients that may not be of primary interest. Further, since exact a values for the exponential features may not be proposed (due to the unknown values of parameters contributing to a), the coefficients of these exponential features 1406 predicted by the optimization algorithm should be such that the linear combination of these features selected will closely represent the actual features. However, the coefficients of the constant feature 1402 and the coefficients of the linear time feature 1404 may be directly correlated in FIG. 14C and FIG. 14D since those are the exact features used as in the actual analytical equation.

In some embodiments, from Equation 6, by writing the equation in the form of RNP and time, the coefficients corresponding to constant and linear time terms can be expressed as Equation 16.

$${c}_{c onst} = 70.6 * \frac{π}{3} * \frac{B μ}{k h} * ( \frac{{y}_{e}}{{x}_{f}} ) \qquad ( 16 )$$

$${c}_{lin \_ time} = 70.6 * π * \frac{B μ}{k h} * ( \frac{{y}_{e}}{{x}_{f}} ) * ( \frac{0.00633 k}{{( ϕ μ {c}_{t} )}_{i} {y}_{e}^{2}} )$$

where:
yₑ—distance from fracture to outer boundary, ft
x_{f}—fracture half-length, ft
k—formation permeability, mD
h—net formation thickness, ft
B—formation volume factor, bbl/STB
μ—viscosity, cP
ϕ—porosity
cₜ—total compressibility, 1/psi

In some embodiments, Table 5 displays a comparison between the coefficients of constant and linear time features for datasets consisting of 1000, 5000, and 10000 days. The datasets were generated and trained on 75% of the total data for each case. The results reveal that the coefficients closely match the true values, particularly when the train dataset is longer. The constant and linear term coefficients with 750 days of training data, where the transient flow is still predominant, show relatively higher error as compared to those with 3750 days and 7500 days of trained data, where they are almost identical. This is expected due to limited availability of the data for the first case that restricts the understanding of complete physical behavior of fluid flow. However, the physics relevant to the short term forecast for that case (transient flow behavior dominant) is well captured and that enables a very accurate forecast for the next 250 days (test data) as shown in FIGS. 12A and 12B.

TABLE 5

| | | Predicted | Predicted | Predicted |
|---|---|---|---|---|
| | Actual | Coefficients | Coefficients | Coefficients |
| Features | Coefficients | (Train - 750 days) | (Train - 3,750 days) | (Train - 7,500 days) |
| Constant | 266.15 | 214.2 | 267.3 | 266.38 |
| Linear Time | 0.086 | 0.107 | 0.086 | 0.086 |

### Example 2—Variable Oil Rate—Wattenbarger Model

This example demonstrates forecasting a variable oil rate profile. The synthetic data may be again generated using the Wattenbarger's analytical equation for closed boundary and fractures extending to the reservoir boundary. The hybrid SNR method is used to predict RNP as a function of time variables, even though a variable oil rate is used for generating the synthetic data for training SINDy. There is no need to use superposition time or superposition rate. The synthetic RNP data used for training SINDy is based on the rate profile provided and the corresponding BHP. Once RNP is predicted at a future time, the BHP can be directly used as an input to get the corresponding rate profile.

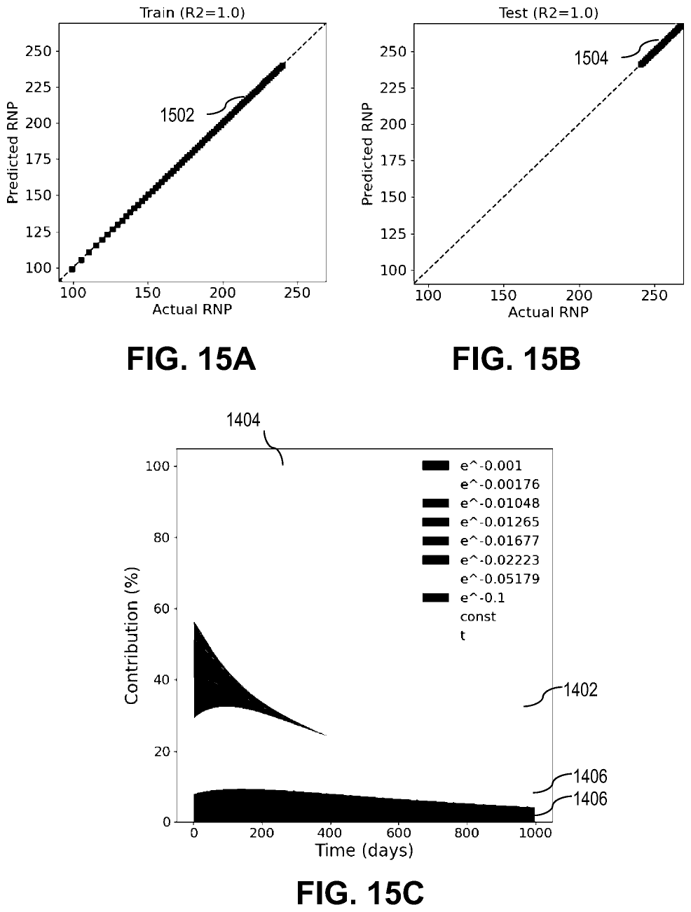

FIGS. 15A-15C illustrate plots of predicted vs. actual RNP data for a machine learning training portion (FIG. 15A) and a test portion (FIG. 15B), and a plot showing selected coefficient contribution with time (FIG. 15C), in accordance with certain embodiments. In some embodiments, the same input parameters as in Table 4 of Example 1 are used. The only difference is instead of a constant rate profile, a variable rate profile is used. Following the same procedure to train SINDy using the proposed candidate features based on Wattenbarger's equation, the results produced are shown in FIGS. 15A-15C. The hybrid SNR method may be used to train a second model to predict RNP estimates by identifying one or more relevant terms from the 52 candidate features in the candidate feature library. FIG. 15A shows a good consistency 1502 with a R-squared (R2) value of 1.0 in a cross plot of the predict RNP values and the actual RNP data in the machine learning training portion. FIG. 15B shows a good consistency 1504 with an R2 value of 1.0 in a cross plot of the predict RNP values and the actual RNP data in the test portion. The consistency between the predict RNP values and the actual RNP data in the machine learning training portion and the test portion indicates that the second model is accurate to predict the RNP estimates. Thus, the predicted RNP shows an accurate match to the actual RNP as shown in FIGS. 15A and 15B. This is expected since the only change here as compared to Example 1 is the RNP magnitude due to variable rates. Likewise, for any operational scenario with a bottomhole pressure profile, the second model may be used to accurately predict oil rate estimates.

In some embodiments, the features selected and their contributions are shown in FIG. 15C. The second model has eliminated several candidate basis functions and identified ten features to get an accurate match. The ten features include a constant feature 1402, a linear time feature 1404, and eight exponential features 1406. The exponential features 1406 are the short transients that may not be of primary interest. Further, since exact a values for the exponential features cannot be proposed (due to the unknown values of parameters contributing to a), the coefficients of these exponential features 1406 predicted by the optimization algorithm should be such that the linear combination of these features selected will closely represent the actual features.

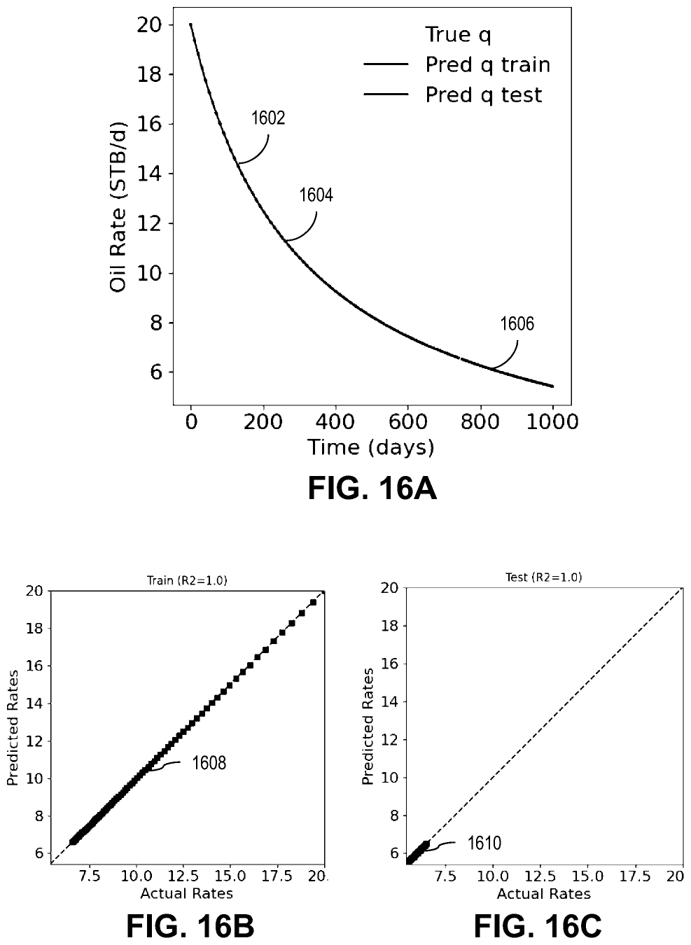

FIGS. 16A-16C illustrate plots of a predicted and an actual oil rate profile (FIG. 16A), and predicted vs. actual flowrate data for a machine learning training portion (FIG. 16B) and a test portion (FIG. 16C), in accordance with certain embodiments. The hybrid SNR method may be used to train the second model to predict oil rate estimates by identifying one or more relevant terms from the 52 candidate features in the candidate feature library. FIG. 16A shows actual oil rate data 1602, predicted oil rate data in the machine learning training portion 1604, and predicted oil rate data in the test portion 1606. FIG. 16B shows a good consistency 1608 with an R2 value of 1.0 in a cross plot of the predict oil rate values and the actual oil rate data in the machine learning training portion. FIG. 16C shows a good consistency 1610 with an R2 value of 1.0 in a cross plot of the predict oil rate values and the actual oil rate data in the test portion. The consistency between the predict oil rate values and the actual oil rate data in the machine learning training portion and the test portion indicates that the second model is accurate to predict the oil rate estimates. Thus, the predicted oil rate shows an accurate match to the actual oil rate as shown in FIGS. 16A, 16B, and 16C.

In some embodiments, the proposed hybrid SNR methods may be validated using the synthetic data generated from Wattenbarger's model and a plurality of features based on the Wattenbarger's equation in Example 1 and Example 2. Likewise, the proposed hybrid SNR method may also use other features described in Table 2 and Table 3 to represent common flow regime diagnostics along with other complex flow conditions.

### Example 3—Multi-Fractured Horizontal Well (MFHW) in Infinite Boundary Reservoir

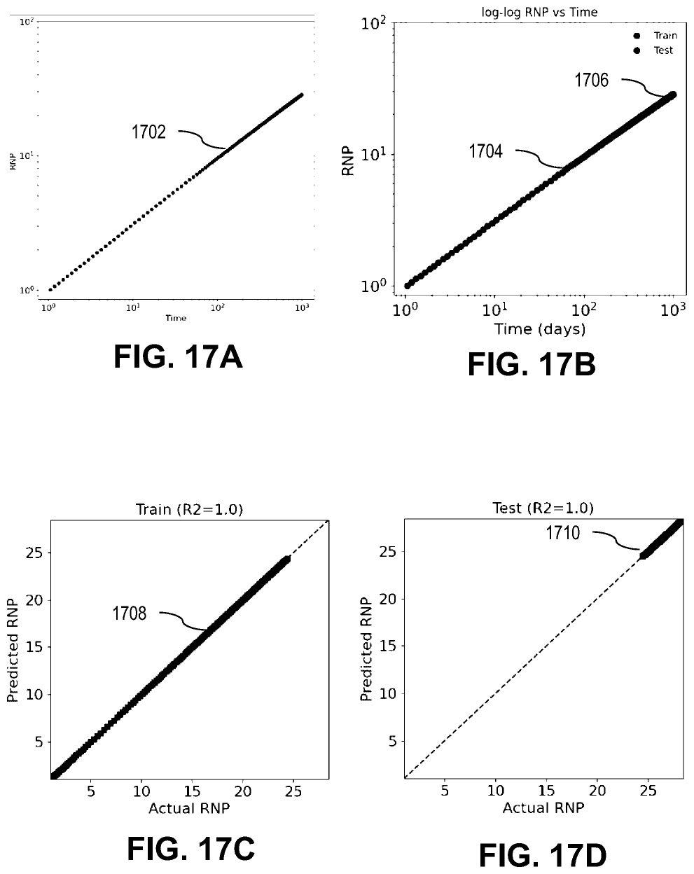

FIGS. 17A-17D illustrate plots of actual RNP vs. time on a log-log plot (FIG. 17A), predicted RNP vs. time on a log-log plot (FIG. 17B), and predicted vs. actual RNP data for a machine learning training portion (FIG. 17C) and a test portion (FIG. 17D), in accordance with certain embodiments. In this example, a plurality of fractures are evenly spaced in an infinite reservoir boundary. The hybrid SNR method may be used to train a third model for a period of 1,000 days at constant rate. For a majority of time, the flow is expected to flow under a transient linear flow regime characterized by half-slope line on RNP and RNP′. FIG. 17A shows the actual RNP data 1702 has predominant regime since the simulation is run for a shorter duration. The third model is trained using a feature library of 61 features (52 based on Wattenbarger's expression and the other 9 corresponding to t^{m} with m ranging from 0.1-0.9 in 0.1 incrementals as explained in Table 2 and Table 3). FIG. 17B show the predicted RNP data for the machine learning training portion 1704 and the predicted RNP data for the test portion 1706, which again show accurate match to the actual data 1702. FIG. 17C shows a good consistency 1708 with an R2 value of 1.0 in a cross plot of the predict RNP values and the actual RNP data in the machine learning training portion. FIG. 17D shows a good consistency 1710 with an R2 value of 1.0 in a cross plot of the predict RNP values and the actual RNP data in the test portion. The consistency between the predict RNP values and the actual RNP data in the machine learning training portion and the test portion indicates that the third model may be accurate to predict the RNP estimates.

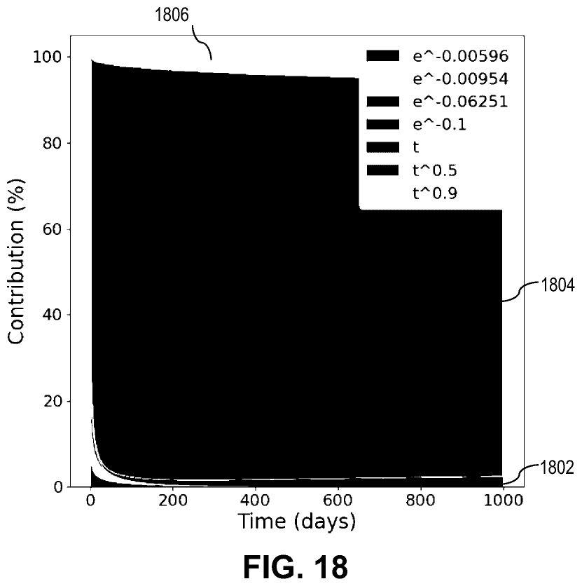

FIG. 18 illustrates a plot showing coefficient contribution with time for an infinite reservoir boundary condition, in accordance with certain embodiments. The third model has successfully identified seven features from the 61 features in the feature library in order to get an accurate match. The seven features include a flow feature 1802 corresponding to t, a flow feature 1804 corresponding to t^{0.5}, and a flow feature 1806 corresponding to t^{0.9}, and four exponential features. FIG. 18 shows almost 95% of the contribution is attributed to the flow feature 1804 corresponding to t^{0.5}, thus validating the effectiveness of the algorithm to identify the predominant flow regime. Minor variations initially and towards the end of the profile from the half slope line could be the reason behind marginal contributions shown by other features.

### Example 4—Closed Boundary with Fracture Length Smaller than Distance to Boundary

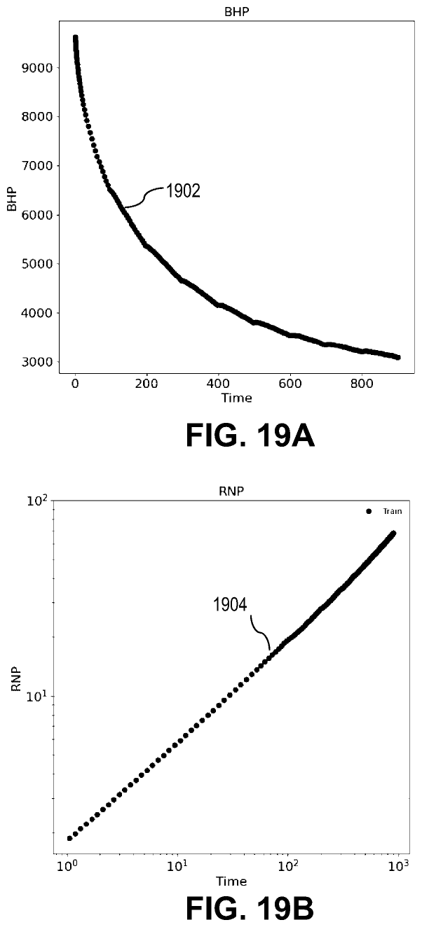

FIGS. 19A and 19B illustrate plots of BHP profile used as an input to a model (FIG. 19A) and a corresponding RNP profile generated for the model (FIG. 19B), in accordance with certain embodiments. In this example, the MFHW has a fracture length not extending to the closed boundary reservoir. Hence a sequence of transient linear flow to transitional flow (subject to fracture spacing) to inter-fracture SRV flow and ultimately BDF at a late time is expected. FIGS. 19A and 19B show the BHP profile 1902 for the variable rate an input to a fourth model and the corresponding RNP vs time profile 1904 for the machine learning training portion on a log-log plot.

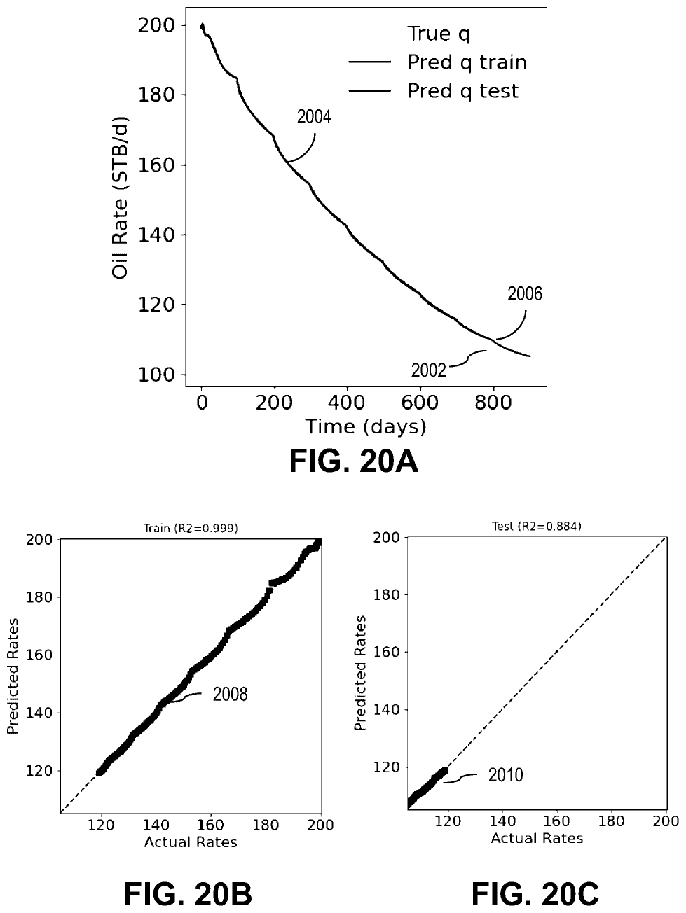

FIGS. 20A-20C illustrate plots of a predicted and an actual oil rate profile (FIG. 20A), and predicted vs. actual flowrate data for a machine learning training portion (FIG. 20B) and a test portion (FIG. 20C), in accordance with certain embodiments. Using 75% of the data for training, FIGS. 20A-20C show comparison of actual rates vs predicted rates. FIG. 20A shows actual oil rate data 2002, predicted oil rate data in the machine learning training portion 2004, and predicted oil rate data in the test portion 2006. FIG. 20B shows a good consistency 2008 with an R2 value of 0.999 in a cross plot of the predict oil rate values and the actual oil rate data in the machine learning training portion. FIG. 20C shows a consistency 2010 with an R2 value of 0.884 in a cross plot of the predict oil rate values and the actual oil rate data in the test portion. The test accuracy is not as high as that of the machine learning training portion. The reason may be attributed to the fact that around the end time of the training period, a transitional flow regime seems to occur after the end of transient linear flow. Thus, this flow regime may not be recognized from the training data.

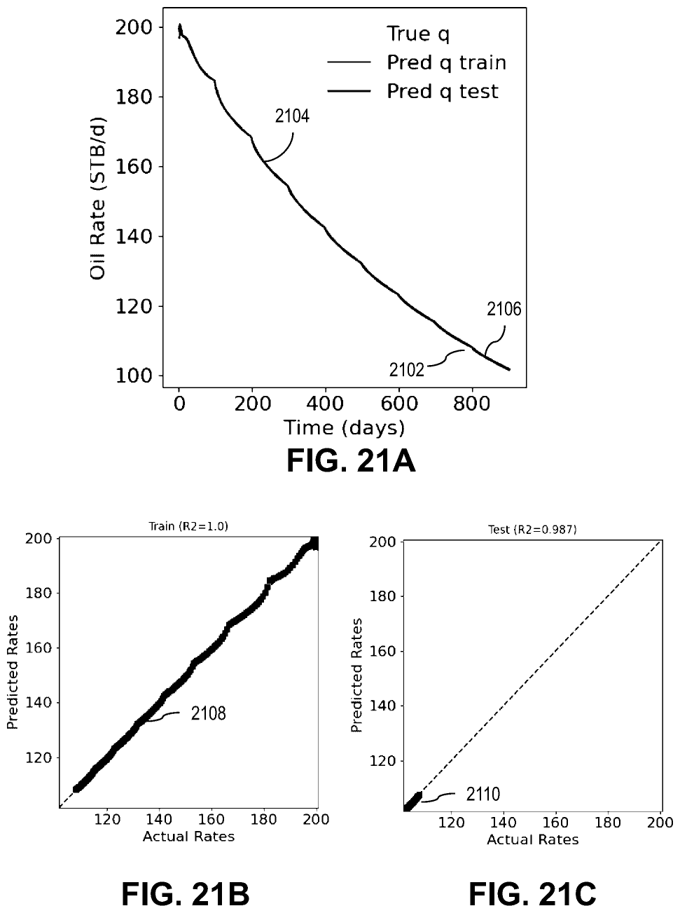

FIGS. 21A-21C illustrate plots of a predicted and an actual oil rate profile (FIG. 21A), and predicted vs. actual flowrate data for a machine learning training portion (FIG. 21B) and a test portion (FIG. 21C), in accordance with certain embodiments. For 90% of data used for training, the test accuracy improves significantly, as shown in FIGS. 21A-21C, since the training data now has the transitional flow period signature to learn from. FIG. 21A shows actual oil rate data 2102, predicted oil rate data in the machine learning training portion 2104, and predicted oil rate data in the test portion 2106. FIG. 21B shows a good consistency 2108 with an R2 value of 1.0 in a cross plot of the predict oil rate values and the actual oil rate data in the machine learning training portion. FIG. 21C shows a consistency 2110 with an R2 value of 0.987 in a cross plot of the predict oil rate values and the actual oil rate data in the test portion.

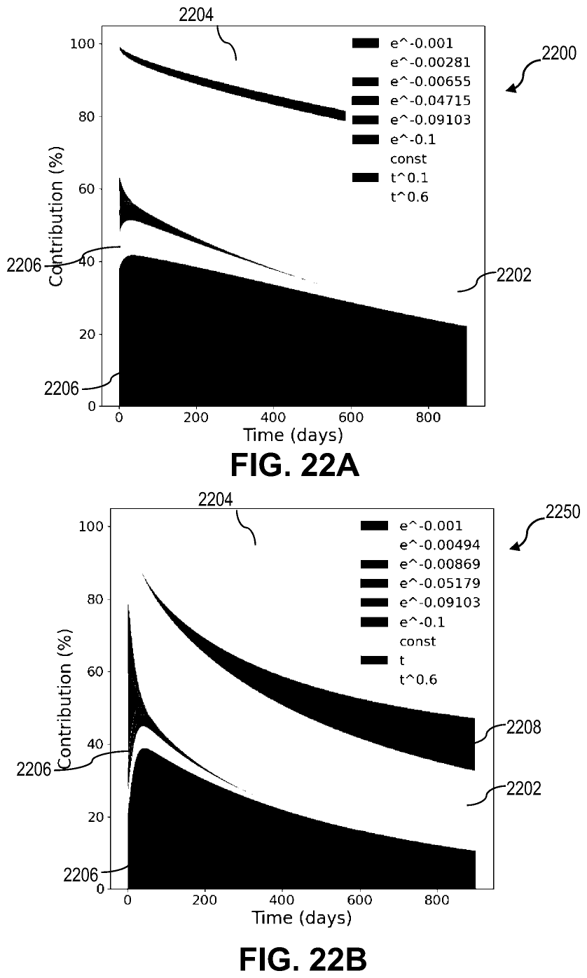

FIGS. 22A and 22B illustrate plots showing coefficient contribution with time for a 75% training data machine learning model and a 90% training data machine learning model, in accordance with certain embodiments. In FIG. 22A, the feature importance map 2200 for the 75% training set shows features mainly corresponding to a constant feature 2202, a flow feature 2204 corresponding to t^{0.6}, and exponential terms 2206. In some embodiments, a linear combination of selected features with their corresponding weights may result in transient linear flow for a majority portion of the training period. In FIG. 22B, the feature importance map 2250 for the 90% training set shows features mainly corresponding to a constant feature 2202, a flow feature 2204 corresponding to t^{0.6}, a flow feature 2208 corresponding to t, and exponential terms 2206. When the training period is extended to 90% of the history, the importance of t^{0.6} and t significantly increases, which corresponds to the trend shifting into a transitional flow regime. Thus, unless a flow regime is seen in the training data, the workflow may not forecast accurately for that flow regime.

In some embodiments, the hybrid SNR method may be very efficient to generate a scalable model which may be applied routinely on a daily frequency or at the frequency at which rate data is available. Thus, the hybrid SNR method may not require any manual intervention or human interpretation. In unconventional reservoirs, a flow regime stays under that regime for a very long period, especially linear flow and SRV flow. Hence the proposed hybrid SNR method is good to use during most time periods especially for short term forecasts. Since the fourth model can be scaled to run automatically on a regular basis, the forecast accuracy will improve as data becomes available for unseen flow regimes.

### Example 5—Closed Boundary with Unevenly Spaced Features

In this example, fractures are not evenly spaced in a closed boundary reservoir. This is a case that represents a complex completion, where many of the fractures are not initiated due to reservoir heterogeneities, operational challenges or improper design considerations. As previously discussed in the section of complex fracture scenarios, a distinct linear transient flow signature would not be visible and hence the standard line fitting procedures and the characteristic equations cannot be applied.

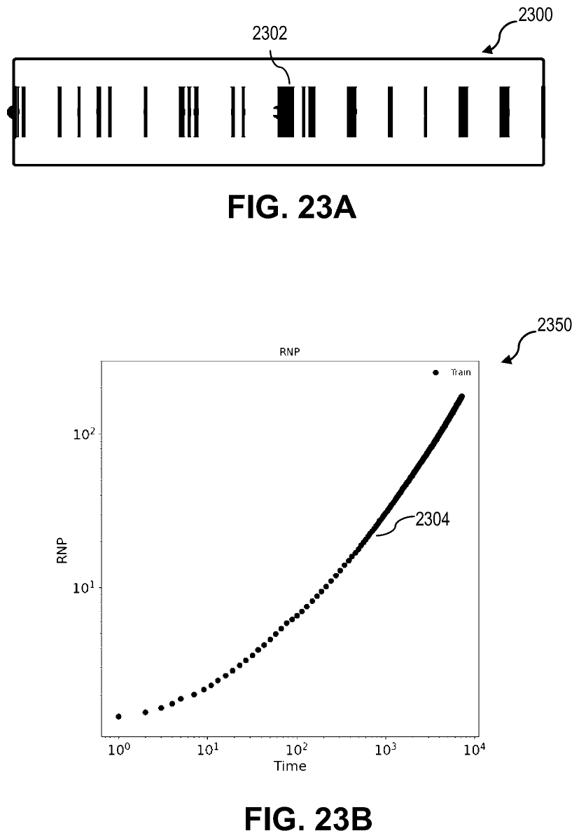

FIG. 23A illustrates a schematic view 2300 of a MFHW with irregular spaced fractures, and FIG. 23B is a log-log plot 2350 of a corresponding RNP profile with respect to time, in accordance with certain embodiments. FIG. 23A shows a fracture model 2302 in which the fracture and reservoir geometry case are simulated for duration of twenty years to generate a BHP profile 2304 for a variable rate constraint and the corresponding RNP profile is shown in FIG. 23B. The fracture model 2302 is generated using the half flow dimension (δ) of 0.3. This stimulation may result in a sub-linear flow since the flowing area is expected to decrease with distance from fracture at a cumulative well level as compared to that if the same fractures were evenly spaced.

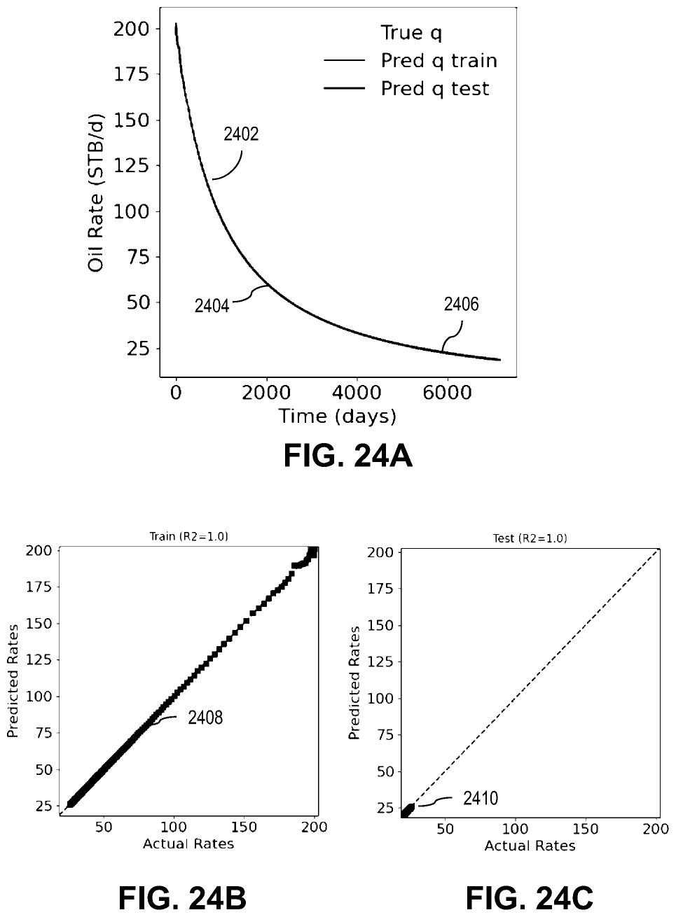

FIGS. 24A-24C illustrate plots of a predicted and an actual oil rate profile (FIG. 24A), and predicted vs. actual flowrate data for a machine learning training portion (FIG. 24B) and a test portion (FIG. 24C), in accordance with certain embodiments. The hybrid SNR method may be used to train a fifth model using 75% of the actual flowrate data. FIG. 24A shows actual oil rate data 2402, predicted oil rate data in the machine learning training portion 2404, and predicted oil rate data in the test portion 2406. FIG. 24B shows a good consistency 2408 with an R2 value of 1.0 in a cross plot of the predict oil rate values and the actual oil rate data in the machine learning training portion. FIG. 24C shows a consistency 2410 with an R2 value of 1.0 in a cross plot of the predict oil rate values and the actual oil rate data in the test portion. Thus, for 75% of data used for training, the predicted oil rate data 2404 and 2406 shows an excellent match to the actual oil rate data 2402 for the closed boundary with unevenly spaced fractures. The consistency between the predict oil rate values and the actual oil rate data in the machine learning training portion and the test portion indicates that the fifth model may be accurate to predict the oil rate estimates.

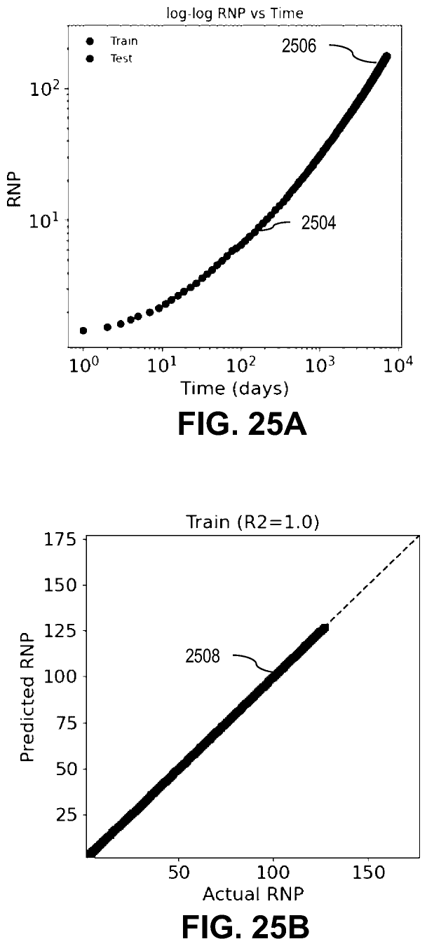

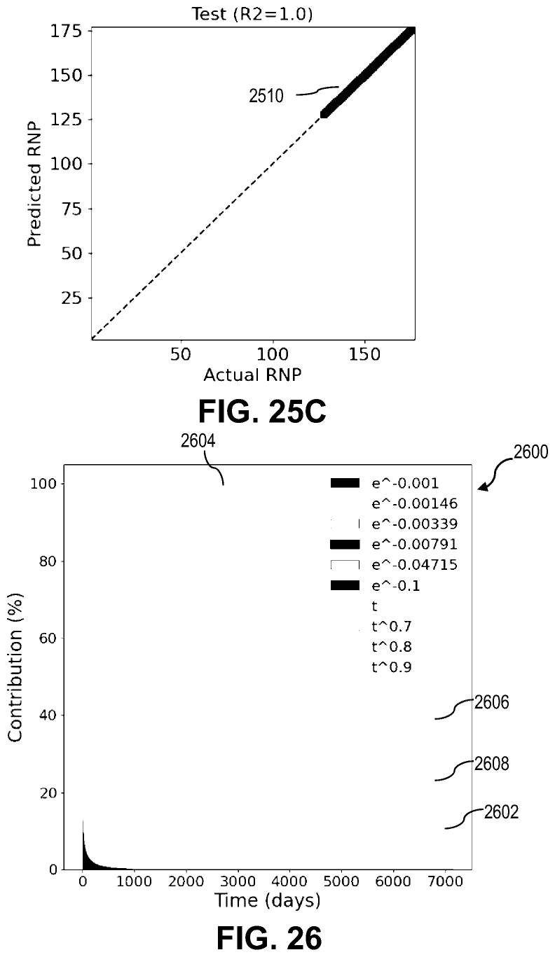

FIGS. 25A-25C illustrate plots of a predicted and an actual RNP profile (FIG. 25A), and predicted vs. actual RNP data for a machine learning training portion (FIG. 25B) and a test portion (FIG. 25C), in accordance with certain embodiments. The hybrid SNR method may be used to train the fifth model using 75% of the actual RNP data. FIG. 25A shows predicted RNP data in the machine learning training portion 2504 and predicted RNP data in the test portion 2506. FIG. 25B shows a good consistency 2508 with an R2 value of 1.0 in a cross plot of the predict RNP values and the actual RNP data in the machine learning training portion. FIG. 25C shows a consistency 2510 with an R2 value of 1.0 in a cross plot of the predict RNP values and the actual RNP data in the test portion. Thus, for 75% of data used for training, the predicted RNP values also show an excellent match to the actual RNP data for the closed boundary with unevenly spaced fractures. The consistency between the predict RNP values and the actual RNP data in the machine learning training portion and the test portion indicates that the fifth model is accurate to predict the RNP estimates. FIG. 26 illustrates a plot showing coefficient contribution with time for a closed boundary condition with unevenly spaced fractures, in accordance with certain embodiments. The feature importance map 2600 for the 75% training set shows features mainly corresponding to a flow feature 2602 corresponding to t, a flow feature 2604 corresponding to t^{0.9}, a flow feature 2606 corresponding to t^{0.8}, and a flow feature 2608 corresponding to t^{0.7}. The features selected and their corresponding contributions fall in line with the RNP trend where the slope shows a continuous change right from the onset of production with that remaining largely greater 0.7 for majority of the history and gradually transitioning into a unit slope. This shows the ability of the algorithm to pick up complex non-linear fluid flow behavior that cannot be limited to a single slope line and using a characteristic equation for that slope.

### Example 6—Unequal Fracture Lengths with Finite Conductivity in Closed Boundary Reservoir

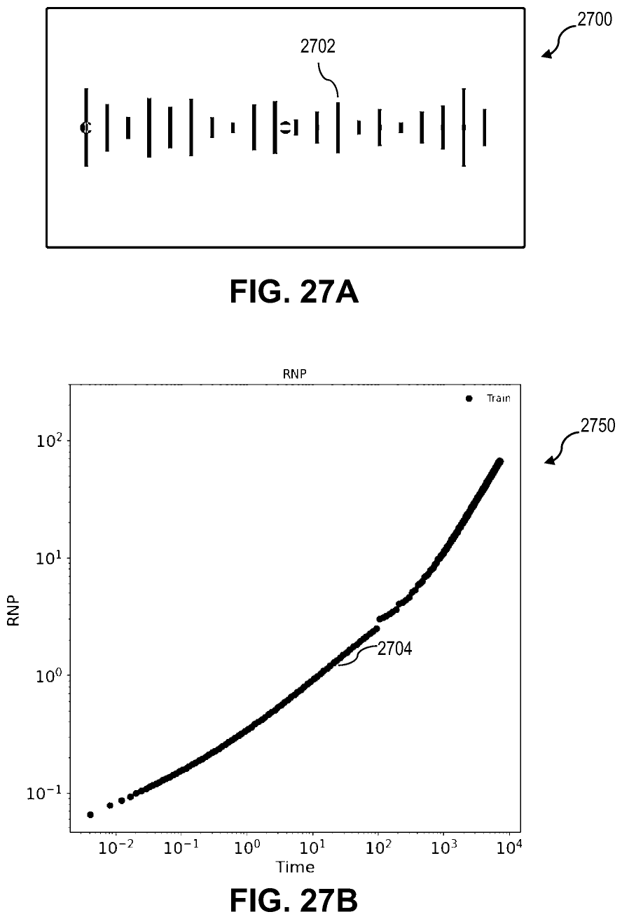

FIG. 27A illustrates a schematic view 2700 of a MFHW with unequal fracture half lengths, and FIG. 27B is a log-log plot 2750 of a corresponding RNP profile with respect to time, in accordance with certain embodiments. FIG. 27A shows a complex fracture network model which represents a practical scenario of a plurality of fractures 2702 with unequal fracture lengths which may be attributed to geomechanical impacts, operational constraints and completions ineffectiveness between stages. Also, finite conductivity fractures are considered and hence it can result in early sub-radial flow with area to flow gradually increasing in some fractures in combination with linear to transitional to SRV flow. Thus, a typical RTA based flow regime analysis here is not practical to perform with simultaneous flow regimes co-occurring. The complex fracture network model with closed reservoir boundary is simulated for a period of twenty years. The corresponding RNP profile 2704 on log-log plot is shown in FIG. 27B, which depicts variable slopes as suspected of such fracture complexity.

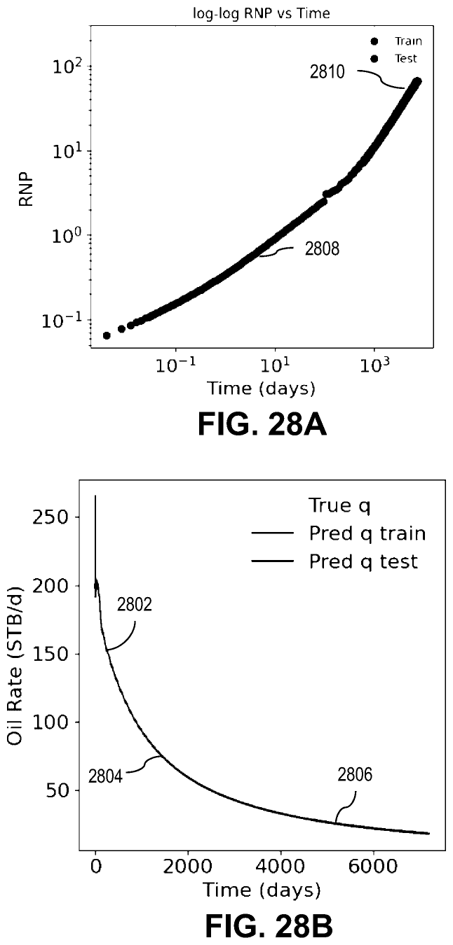

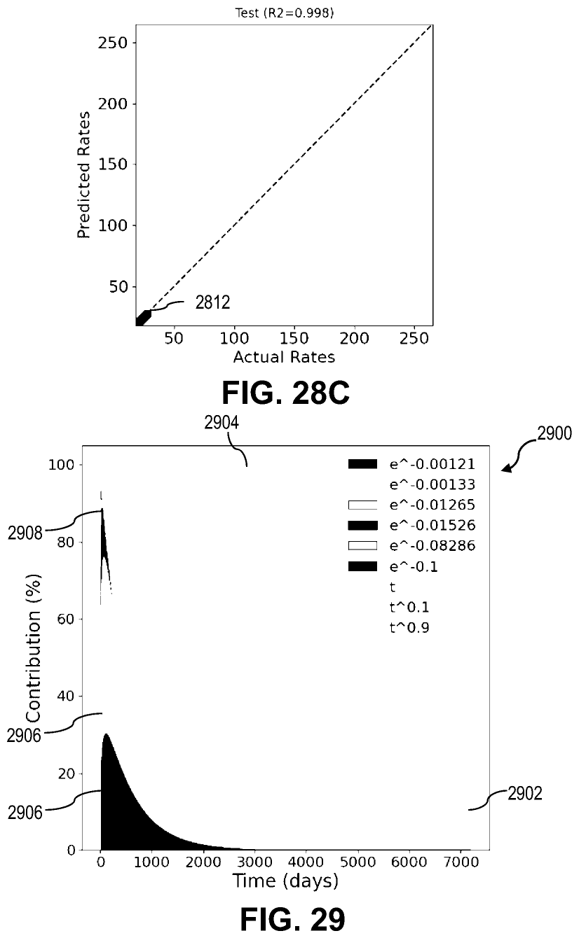

FIGS. 28A-28C illustrate plots of a predicted and an actual RNP profile (FIG. 28A), a predicted and actual oil rate profile (FIG. 28B) with respect to time, and predicted vs. actual flowrate data for a test portion (FIG. 28C), in accordance with certain embodiments. The hybrid SNR method may be used to train a sixth model using 75% of the actual RNP data. FIG. 28A shows predicted RNP data in the machine learning training portion 2808 and predicted RNP data in the test portion 2810. FIG. 28B shows actual oil rate data 2802, predicted oil rate data in the machine learning training portion 2804, and predicted oil rate data in the test portion 2806. FIG. 28C shows a consistency 2812 with an R2 value of 0.998 in a cross plot of the predict flowrate values and the actual flowrate data in the test portion. FIGS. 28A-28C show the RNP for train and test cases and the corresponding rate profile compared to the actual rates. The match again is very accurate confirming the ability of the sixth model to identify the most relevant features in a way that depicts the entire history and to maintain its validity for the forecasts.

FIG. 29 illustrates a plot 2900 showing coefficient contribution with time for a closed boundary condition with unequal fracture lengths and finite conductivity, in accordance with certain embodiments. For initial 500 days, the flow is dominated by a combination of exponential features 2906 and a sub-radial flow feature 2908 with a time slope of 0.1, followed by a linear flow and then gradually transitioning into two SRV flow features 2902 and 2904 where t and t^{0.9} are dominant, respectively.

### Example 7—Field Case—Gas Well

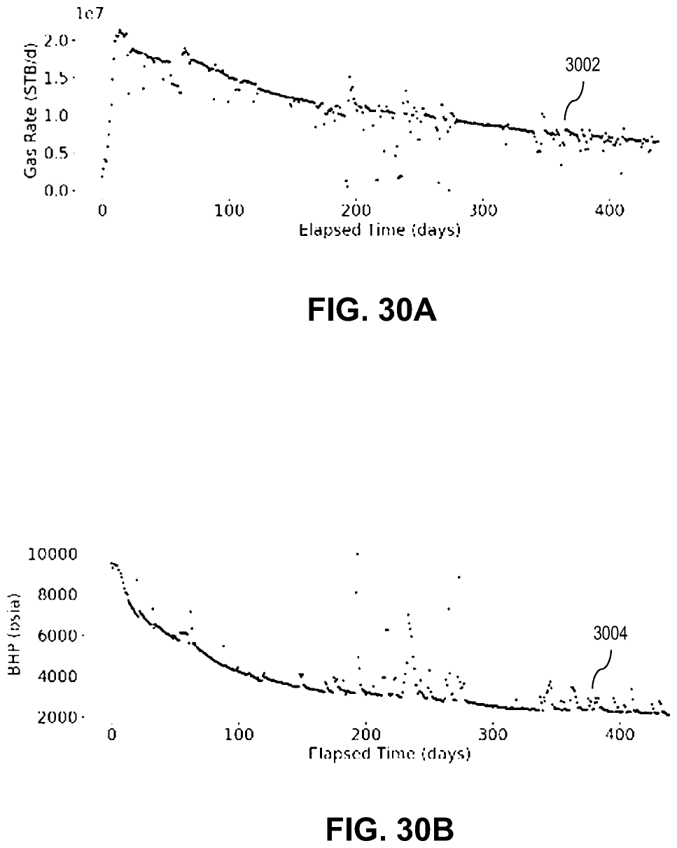

FIGS. 30A and 30B illustrate plots of measured gas rates and BHP, respectively, with respect to time for a gas well, in accordance with certain embodiments. In this example, a real field case is considered for an onshore US basin well with dry gas as the primary producing phase. FIGS. 30A and 30B show the gas rates 3002 and corresponding BHPs 3004, respectively, calculated for the well under consideration.

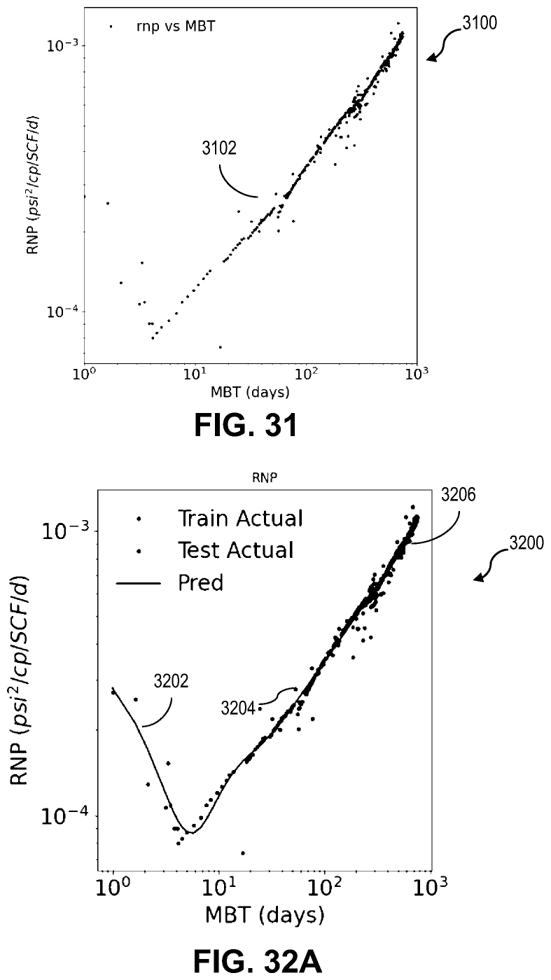

FIG. 31 illustrates a plot 3100 of gas RNP vs material balance time (MBT) for the gas well, in accordance with certain embodiments. Since real field scenarios are not expected to produce smooth rate profiles as observed in the synthetic models, it is expected for the RNP vs. time trend 3102 to show these impacts of noise. Using RNP as a function of MBT effectively handles the noisy data for hybrid SNR analysis. MBT normalizes RNP by providing a constant-rate equivalent for variable flow rate/variable pressure drop data. In some embodiments, RNP is calculated using pseudo pressures as defined in Equation 9 for gas wells,

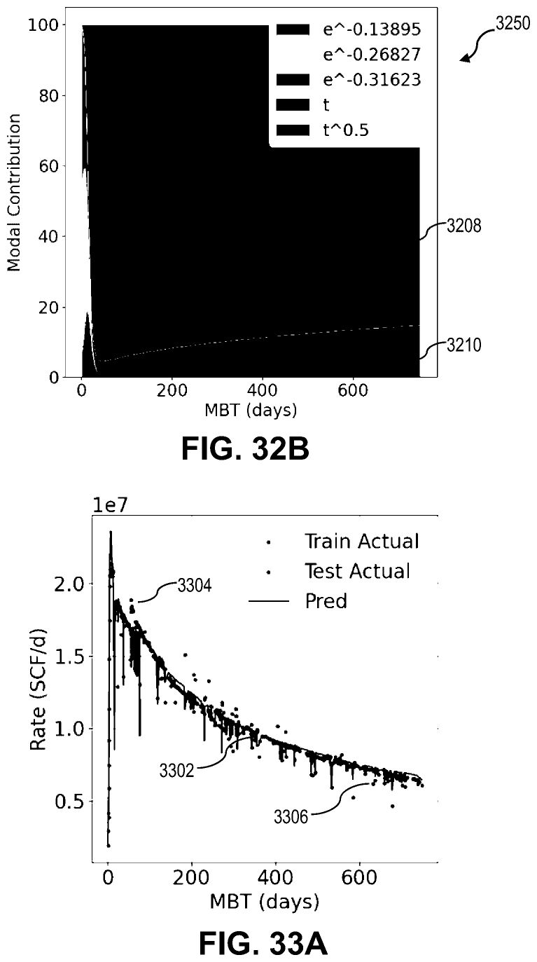

FIG. 32A illustrates a plot 3200 of predicted and actual gas RNP with respect to MBT for the gas well, in accordance with certain embodiments. FIG. 32B illustrates a plot 3250 showing coefficient contribution with MBT for the gas well, in accordance with certain embodiments. The observed samples were split into 75% training data 3204 and 25% test data 3206. The training samples 3204 are used to train a seventh model as formulated with physics inspired features. The resultant model RNP predictions 3202 are then used to predict rates for the actual BHPs implemented during the test phase to compare against actual rates. FIG. 32B shows the feature contribution map includes a dominant t^{0.5} feature 3208 during a major part of the training period and gradually increasing contribution from the linear t feature 3210. In some embodiments, the time features use MBT function of time. This example shows how the resulting RNP equation indicates at any given time multiple flow regimes can co-exist.

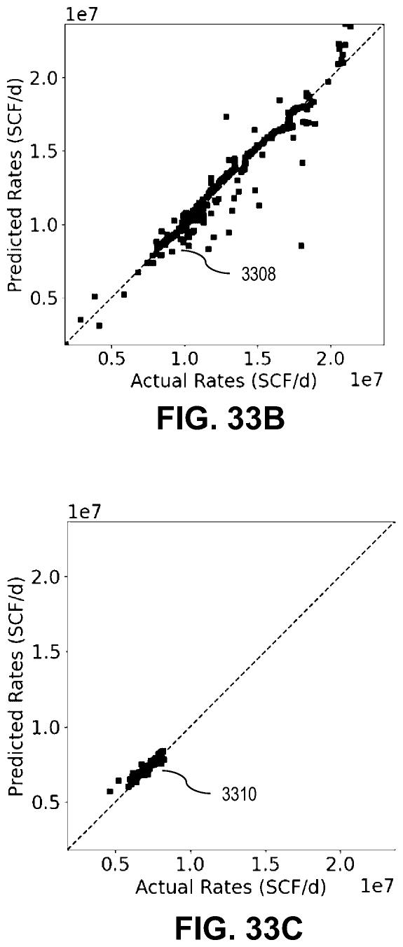

FIGS. 33A-33C illustrate plots of a predicted and an actual gas rate vs. MBT (FIG. 33A), and predicted vs. actual gas rate data for a machine learning training portion (FIG. 33B) and a test portion (FIG. 33C), in accordance with certain embodiments. FIG. 33A shows the training rate data 3304, test rate data 3306, and predicted rate data 3302. FIG. 33B shows a good consistency 3308 in a cross plot of the predict oil rate values and the actual oil rate data in the machine learning training portion. FIG. 33C shows a consistency 3310 in a cross plot of the predict oil rate values and the actual oil rate data in the test portion. FIGS. 33B and 33C show very good accuracy of the seventh model to predict gas rates for the operated BHP. An example of median absolute percentage errors (MedAPE) for the predicted rates may be found in Table 6.

TABLE 6

| Train Gas Rates MedAPE | Test Gas Rates MedAPE |
|---|---|
| 2.5% | 3.4% |

### Example 8—Field Case—Oil Well

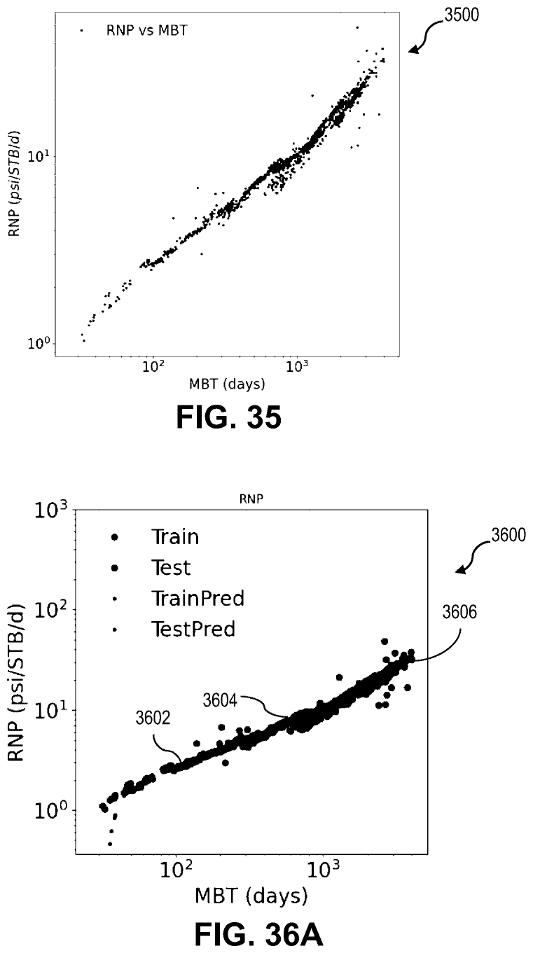

This example is another field case for a well in the US onshore basin with primary oil phase production that has a water cut ranging around 90%. FIG. 35 shows the RNP vs MBT on a log-log plot that is used to sample the train (75%) and test (25%) sets.

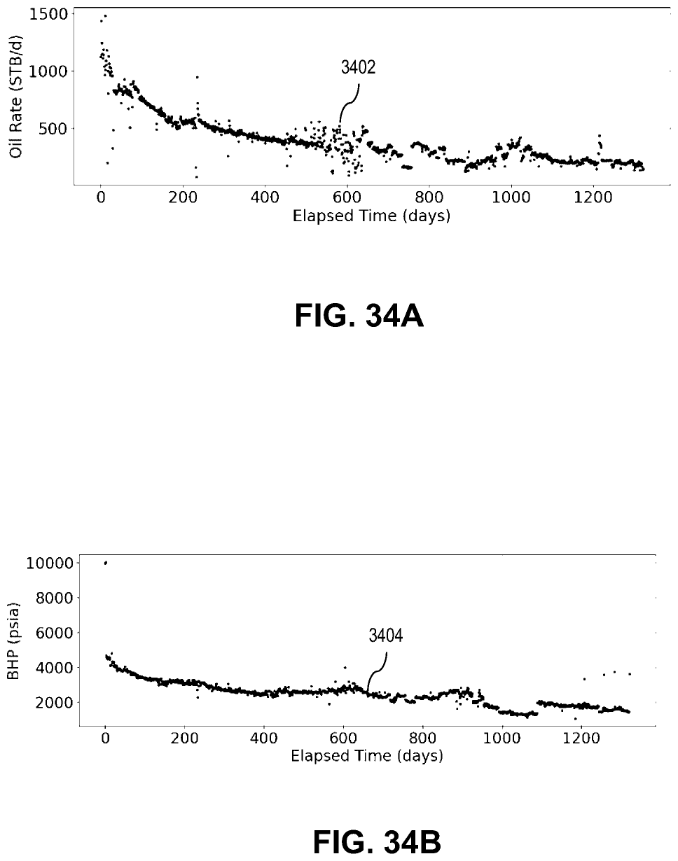

FIGS. 34A and 34B illustrate plots of measured oil rates 3402 and BHP 3404, respectively, with respect to time for an oil well, in accordance with certain embodiments.

FIG. 35 illustrates a plot 3500 of oil RNP vs material balance time (MBT) for the oil well, in accordance with certain embodiments. FIG. 35 shows the RNP vs MBT on a log-log plot that is used to sample the 75% training data and the 25% test data. This is a multi-phase case with predominantly liquid production. Thus, it is useful to derive both liquid and oil rate predictions using the proposed hybrid SNR method since the formulation is generic to apply to any phase independently and may be able to identify the underlying governing equations for any phase.

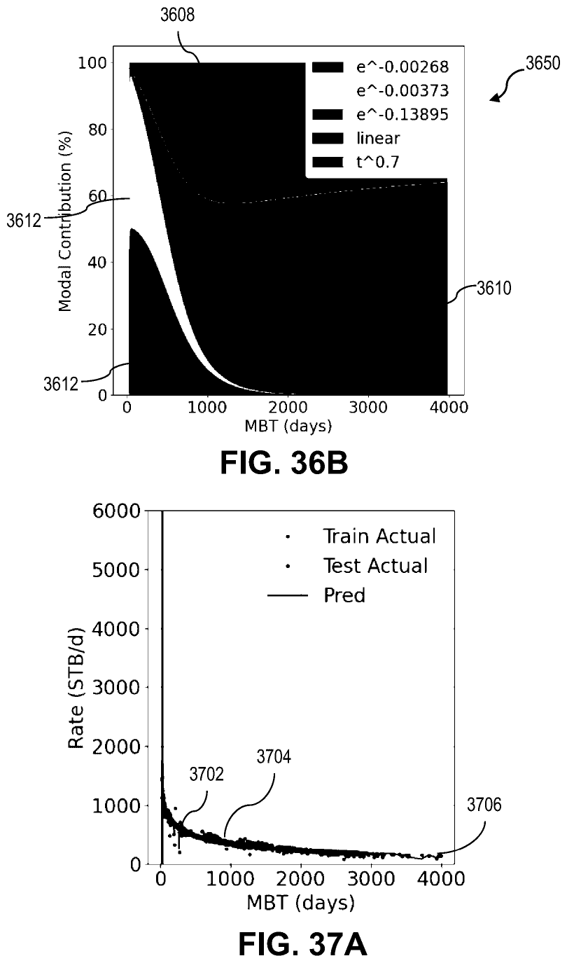

FIG. 36A illustrates a plot 3600 of predicted and actual oil RNP with respect to MBT for the oil well, in accordance with certain embodiments. The proposed hybrid SNR method is used to determine an eighth model by using the actual oil RNP data for the machine learning training portion 3604 and the actual oil RNP data for the test portion 3606. Thus, the proposed hybrid SNR method may be used to predict oil RNP estimates 3602 based on the eighth model.

FIG. 36B illustrates a plot 3650 showing coefficient contribution with MBT for oil production from the oil well, in accordance with certain embodiments. The feature contribution map indicates coexistence of multiple flow regime signatures through a dominant t^{0.7} feature 3608 and a linear feature 3610 of MBT. The exponential terms 3612 are dominating initially, which die down after approximately 2000 MBT days. The ability of the algorithm to pick up simultaneous flow profiles is also evident from non-linearities that seem to exist in the RNP plot rather than what a classical RTA workflow would have done by fitting straight lines with certain pre-defined slopes to it.

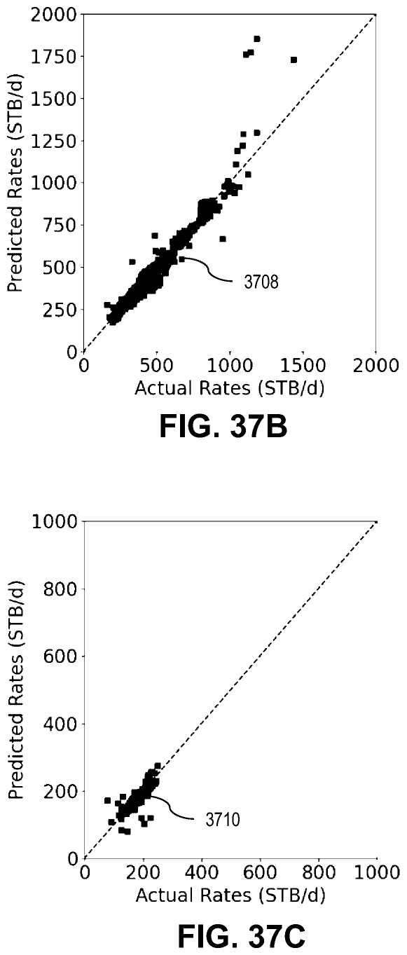

FIGS. 37A-37C illustrate plots of a predicted and an actual oil rate vs. MBT (FIG. 37A), and predicted vs. actual oil rate data for a machine learning training portion (FIG. 37B) and a test portion (FIG. 37C), in accordance with certain embodiments. FIG. 37A shows the training rate data 3704, test rate data 3706, and predicted rate data 3702. FIG. 37B shows a good consistency 3708 in a cross plot of the predict oil rate values and the actual oil rate data in the machine learning training portion. FIG. 37C shows a consistency 3710 in a cross plot of the predict oil rate values and the actual oil rate data in the test portion. FIGS. 37B and 37C show very good accuracy of the eighth model to predict gas rates for the operated BHP. In some embodiments, the first 30 points of the production history are filtered out to remove noisy data due to issues with surface measurements initially.

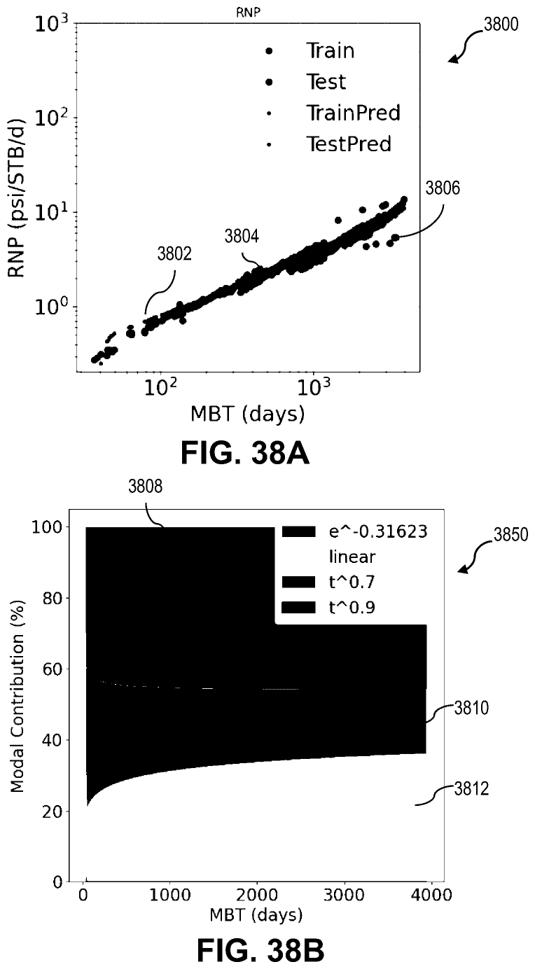

FIG. 38A illustrates a plot 3800 of predicted and actual liquid RNP with respect to MBT for the oil well, in accordance with certain embodiments. FIG. 38A shows the training rate data 3804, test rate data 3806, and predicted rate data 3802.

FIG. 38B illustrates a plot 3850 showing coefficient contribution with MBT for liquid production from the oil well, in accordance with certain embodiments. The feature contribution map indicates coexistence of multiple flow regime signatures through a flow feature 3808 corresponding to t^{0.9}, a flow feature 3810 corresponding to t^{0.7}, and a linear feature 3812 of MBT. The ability of the algorithm to pick up simultaneous flow profiles is also evident from non-linearities that seem to exist in the RNP plot rather than what a classical RTA workflow would have done by fitting straight lines with certain pre-defined slopes to it. Thus, the RNP profile is dominated by sublinear-linear flow regime that simultaneously exist and there is just one exponential term selected by the algorithm that has almost negligible contribution quickly decaying in the beginning.

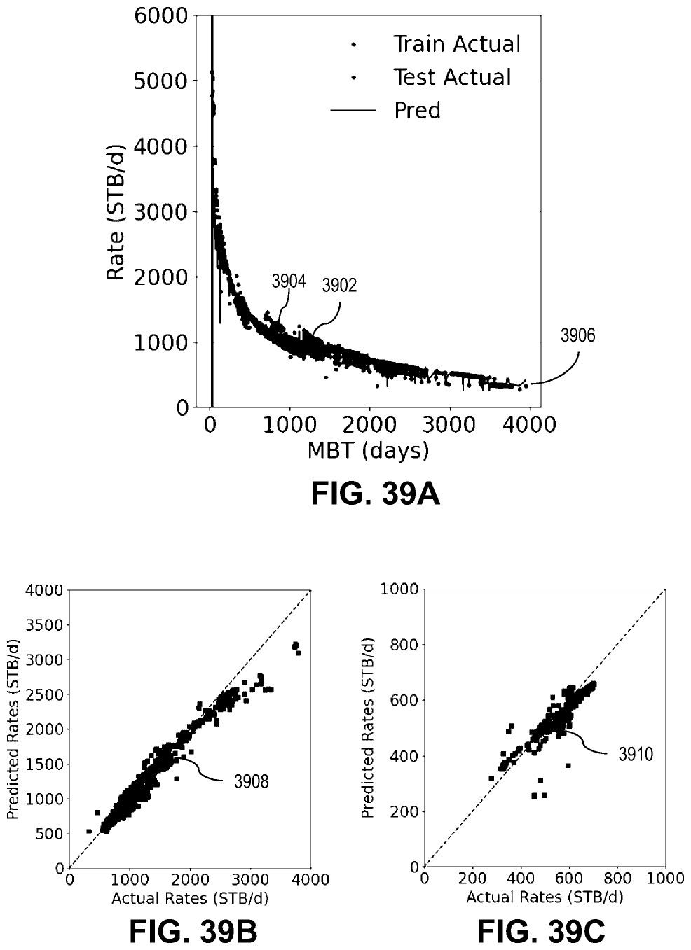

FIGS. 39A-39C illustrate plots of a predicted and an actual liquid rate vs. MBT (FIG. 39A), and predicted vs. actual liquid rate data for a machine learning training portion (FIG. 39B) and a test portion (FIG. 39C), in accordance with certain embodiments. FIG. 39A shows the training rate data 3904, test rate data 3906, and predicted rate data 3902. FIG. 39B shows a good consistency 3908 in a cross plot of the predict liquid rate values and the actual liquid rate data in the machine learning training portion. FIG. 39C shows a consistency 3910 in a cross plot of the predict liquid rate values and the actual liquid rate data in the test portion. FIGS. 39B and 39C show very good accuracy of the eighth model to predict liquid rates for the operated BHP. Based on the predicted RNP, liquid rates are predicted for the operating BHP profile and compared against actual rates as shown in FIGS. 39A-39C. The median absolute percentage error for both oil and liquid rates for train and test sets are shown in Table 7.

TABLE 7

| | Train Rates MedAPE | Test Rates MedAPE |
|---|---|---|
| Oil | 4.7% | 3.8% |
| Liquid | 6.0% | 4.8% |

In some embodiments, a hybrid SNR based formulation, namely SINDy has been proposed with the goal to discover fluid flow dynamics in MFHWs by identifying relationships between rates of fluid phases and bottomhole pressures. The disclosed methods utilize a library of physics inspired functions to capture dominant fluid flow behaviors in unconventional reservoirs. It was shown through several case studies that the methods can capture fluid flow behavior in complex, non-uniform fractures that follows a complex diagnostics behavior not explained by analytical equations. The hybrid SNR approach identifies these complexities from a combination of the most relevant pressure and time features that explain the phase rates behavior for a given well, thus enables forecasting the well for different flowing pressure/operating conditions.

The proposed workflow is highly scalable and computationally efficient, making it possible to be applied daily or at the frequency of available rate data. It does not need any manual intervention or human interpretation when applied at scale. The proposed workflow is good to use during most time periods, especially for short term forecasts. Since the model can be scaled to run automatically on a regular basis, the forecast accuracy tends to improve as data becomes available for unseen flow regimes.

Modifications, additions, or omissions may be made to the systems and apparatuses described herein without departing from the scope of the disclosure. The components of the systems and apparatuses may be integrated or separated. Moreover, the operations of the systems and apparatuses may be performed by more, fewer, or other components. Additionally, operations of the systems and apparatuses may be performed using any suitable logic comprising software, hardware, and/or other logic. As used in this document, “each” refers to each member of a set or each member of a subset of a set.

Modifications, additions, or omissions may be made to the methods described herein without departing from the scope of the invention. For example, the steps may be combined, modified, or deleted where appropriate, and additional steps may be added. Additionally, the steps may be performed in any suitable order without departing from the scope of the present disclosure.

Although the present invention has been described with several embodiments, a myriad of changes, variations, alterations, transformations, and modifications may be suggested to one skilled in the art, and it is intended that the present invention encompass such changes, variations, alterations, transformations, and modifications as fall within the scope of the appended claims. Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee. The indefinite articles “a” or “an,” as used in the claims, are each defined herein to mean one or more than one of the element that it introduces.

A number of examples have been described. Nevertheless, it will be understood that various modifications can be made. Accordingly, other implementations are within the scope of the following claims.

What is claimed is:

1. A method of forecasting production of a well penetrating a reservoir in a subterranean formation, comprising:
receiving a plurality of bottomhole pressures for the well;
receiving a plurality of flowrates for the well;
determining rate normalized pressure (RNP) data for the well over a period of time based on the plurality of bottomhole pressures and the plurality of flowrates;
performing a sparse identification of nonlinear dynamics (SINDy) analysis on the RNP data to identify a relationship between flowrate and bottomhole pressure for the well, wherein the SINDy analysis is based on a plurality of physics features in a regression library;
providing a forecast of future production for the well based on the identified relationship between flowrate and bottomhole pressure for the well; and
producing fluids from the reservoir based, at least in part, on the forecast of future production.

2. The method of claim 1, wherein the plurality of physics features comprise:
a bilinear flow regime;
a fracture linear flow regime;
one or both of a stimulated rock volume flow regime or pseudo steady state flow regime;
a compound linear flow regime; and
one or both of a sub-linear flow regime or a sub-radial flow regime.

3. The method of claim 1, further comprising:
generating the plurality of physics features in the regression library of a fractural flow behavior associated with the reservoir, the regression library including a plurality of selectable data modeling primitives based on a plurality of data-driven and physics-motivated basis functions.

4. The method of claim 3, wherein the plurality of physics features comprise constant, polynomial, logarithmic, exponential, and trigonometric functions.

5. The method of claim 1, further comprising:
performing the SINDy analysis in a data-driven workflow to determine a sparse model of the relationship between flowrate and bottomhole pressure for the well based on routinely available data.

6. The method of claim 5, wherein the sparse model is determined using a convex L1-norm regularized regression.

7. The method of claim 1, further comprising:
performing the SINDy analysis to determine a sparse vector of coefficients associated with the plurality of physics features for the plurality of bottomhole pressures and the plurality of flowrates for the well.

8. The method of claim 7, further comprising:
determining one or more active terms in the regression library based on the sparse vector of coefficients associated with the plurality of physics features of the regression library.

9. A system of forecasting production of a well penetrating a reservoir in a subterranean formation, comprising:
one or more processors; and
one or more computer-readable non-transitory storage media comprising instructions that, when executed by the one or more processors, cause one or more components of the system to perform operations comprising:
receiving a plurality of bottomhole pressures for the well;
receiving a plurality of flowrates for the well;
determining rate normalized pressure (RNP) data for the well over a period of time based on the plurality of bottomhole pressures and the plurality of flowrates;
performing a sparse identification of nonlinear dynamics (SINDy) analysis on the RNP data to identify a relationship between flowrate and bottomhole pressure for the well, wherein the SINDy analysis is based on a plurality of data-driven features in a regression library; and
providing a forecast of future production for the well based on the identified relationship between flowrate and bottomhole pressure for the well.

10. The system of claim 9, wherein the plurality of data-driven features comprise features selected from the group consisting of:
a fracture storage regime;
a bilinear flow regime;
a fracture linear flow regime;
one or both of a stimulated rock volume flow regime or pseudo steady state flow regime; a compound linear flow regime;
a dual permeability or porosity regime;
a pseudoradial flow regime;
a pseudosteady state regime;
a steady state regime; and
one or both of a sub-linear flow regime or a sub-radial flow regime.

11. The system of claim 9, the operations further comprising:
generating the plurality of data-driven features in a regression library of a fractural flow behavior associated with the reservoir, the regression library including a plurality of selectable data modeling primitives based on a plurality of data-driven and physics-motivated basis functions.

12. The system of claim 11, wherein the plurality of data-driven features comprise constant, polynomial, logarithmic, exponential, and trigonometric functions.

13. The system of claim 9, the operations further comprising:
performing the SINDy analysis in a data-driven workflow to determine a sparse model of the relationship between flowrate and bottomhole pressure for the well based on routinely available data.

14. The system of claim 13, wherein the sparse model is determined using a convex L1-norm regularized regression.

15. The system of claim 9, the operations further comprising:
performing the SINDy analysis to determine a sparse vector of coefficients associated with the plurality of data-driven features for the plurality of bottomhole pressures and the plurality of flowrates for the well.

16. The system of claim 15, the operations further comprising:
determining one or more active terms in the regression library based on the sparse vector of coefficients associated with the plurality of data-driven features of the regression library.

17. A method of forecasting production of a well penetrating a reservoir in a subterranean formation, comprising:
receiving a plurality of bottomhole pressures for the well;
receiving a plurality of flowrates for the well;
training a machine learning model based on the plurality of bottomhole pressures and the plurality of flowrates for the well;
performing a sparse nonlinear regression (SNR) analysis on the machine learning model to predict future production of the well, wherein the SNR analysis is based on a plurality of physics features in a regression library; and
producing fluids from the reservoir based, at least in part, on the predicted future production of the well.

18. The method of claim 17, further comprising:
during or after producing the fluids, receiving one or more additional bottomhole pressures for the well and one or more additional flowrates for the well; and
updating the machine learning model based on the additional bottomhole pressures and additional flowrates for the well.

19. The method of claim 17, wherein the physics features comprise features selected from the group consisting of:
a fracture storage regime;
a bilinear flow regime;
a fracture linear flow regime;
one or both of a stimulated rock volume flow regime or pseudo steady state flow regime;
a compound linear flow regime;
a dual permeability or porosity regime;
a pseudoradial flow regime;
a pseudosteady state regime;
a steady state regime; and
one or both of a sub-linear flow regime or a sub-radial flow regime.

20. The method of claim 17, wherein the SNR analysis comprises a sparse identification of nonlinear dynamics (SINDy) analysis.

21. The method of claim 17, further comprising:
generating the plurality of physics features in a regression library of a fractural flow behavior associated with the reservoir, the regression library including a plurality of selectable data modeling primitives based on a plurality of data-driven and physics-motivated basis functions.

22. The method of claim 21, wherein the plurality of data-driven features comprise constant, polynomial, logarithmic, exponential, and trigonometric functions.

23. The method of claim 17, further comprising:
performing the SNR analysis in a data-driven workflow to determine a sparse model of a relationship between flowrate and bottomhole pressure for the well based on routinely available data.

24. The method of claim 23, wherein the sparse model is determined using a convex L1-norm regularized regression.

25. The method of claim 17, further comprising:
performing the SNR analysis to determine a sparse vector of coefficients associated with the plurality of physics features for the plurality of bottomhole pressures and the plurality of flowrates for the well.

26. The method of claim 25, further comprising:
determining one or more active terms in the regression library based on the sparse vector of coefficients associated with the plurality of physics features of the regression library.

27. A system of forecasting production of a well penetrating a reservoir in a subterranean formation, comprising:
one or more processors; and
one or more computer-readable non-transitory storage media comprising instructions that, when executed by the one or more processors, cause one or more components of the system to perform operations comprising:
receiving a plurality of bottomhole pressures for the well;
receiving a plurality of flowrates for the well;
training a machine learning model based on the plurality of bottomhole pressures and the plurality of flowrates for the well; and
performing a sparse nonlinear regression (SNR) analysis on the machine learning model to predict future production of the well, wherein the SNR analysis is based on a plurality of physics and/or data-driven features in a regression library.

28. The system of claim 27, the operations further comprising:
producing fluids from the reservoir based, at least in part, on the predicted future production of the well;
during or after producing the fluids, receiving one or more additional bottomhole pressures for the well and one or more additional flowrates for the well; and
updating the machine learning model based on the additional bottomhole pressures and additional flowrates for the well.

29. A method of forecasting production of a well penetrating a reservoir in a subterranean formation, comprising:
receiving a plurality of bottomhole pressures for the well;
receiving a plurality of flowrates for the well;
determining rate normalized pressure (RNP) data for the well based on the plurality of bottomhole pressures and the plurality of flowrates;
training a machine learning model based on the RNP data for the well;
performing a sparse nonlinear regression (SNR) analysis on the machine learning model to predict future RNP values for the well, wherein the SNR analysis is based on a plurality of physics and/or data-driven features in a regression library; and
producing fluids from the reservoir based, at least in part, on the future RNP values for the well.

30. The method of claim 29, further comprising:
during or after producing the fluids, receiving one or more additional bottomhole pressures for the well and one or more additional flowrates for the well;
determining additional RNP data for the well based on the additional bottomhole pressures and additional flowrates; and
updating the machine learning model based on the additional RNP data for the well.
